(19) United States
(12) Patent Application Publication
(10) Pub. No.: US 2026/0324223 A1
(43) Pub. Date: Oct. 15, 2026

(54) DISPLAY DEVICE AND REPAIRING METHOD THEREOF

(71) Applicant: LG Display Co., Ltd., Seoul (KR)

(72) Inventors: Eunjin OH, Paju-si (KR); Sang-Woo KIM, Paju-si (KR)

(73) Assignee: LG Display Co., Ltd., Seoul (KR)

(21) Appl. No.: 19/465,444

(22) Filed: Jan. 30, 2026

(30) Foreign Application Priority Data
Feb. 28, 2025 (KR) 10-2025-0026530

(51) Int. Cl. H10K 59/131; H10K 59/12; H10K 59/121; H10K 59/35; H10K 71/00

(52) U.S. Cl. CPC H10K 59/131; H10K 59/1201; H10K 59/1213; H10K 59/35; H10K 71/861

(57) ABSTRACT

A display device includes a substrate; a pixel on the substrate, the pixel including a pixel circuit connected between a first power line configured to supply a first power voltage and a second power line configured to supply a second power voltage, and a light emitting element connected to the pixel circuit; a welding electrode on the substrate; a first auxiliary line having one end connected to at least one node connected to the pixel circuit and the other end disposed to be connectable to the welding electrode; and a second auxiliary line having one end connected to the welding electrode and the other end connected to the second power line.

### CROSS-REFERENCE TO RELATED APPLICATIONS

This application claims the priority of Korean Patent Application No. 10-2025-0026530 filed on Feb. 28, 2025, in the Korean Intellectual Property Office, the disclosure of which is hereby incorporated herein by reference.

### BACKGROUND

### Technical Field

The present disclosure relates to a display device and a repair method thereof, and more particularly, to a display device capable of repairing a defective pixel and a repair method thereof.

### Discussion of the Related Art

As it enters the information age, a display field for visually expressing electrical information signals has been rapidly developed, and in response to this, various display devices having excellent performances, such as thin profile, reduced weight, and low power consumption, have been developed. Examples of the display device include a liquid crystal display device (LCD) and an organic light emitting display device (OLED).

Meanwhile, defective pixels may occur during the manufacturing process of the display device (display panel). By such a defective pixel, a bright spot that always emits light or a dark spot that never emits light may be present on the display panel of the display device regardless of the gate signal and the data signal. In addition, as the display device is developed with a large area and high resolution, the number of pixels increases, thereby increasing the probability of occurrence of such defects in at least one pixel of the display device. Accordingly, there is a need for a method for repairing a defective pixel to increase the yield of the display device.

### SUMMARY

Accordingly, embodiments of the present disclosure are directed to a display device that substantially obviates one or more of the problems due to limitations and disadvantages of the related art.

An aspect of the present disclosure is to provide a display device capable of repairing a defective pixel and a repair method thereof.

Another aspect of the present disclosure is to provide a display device that minimizes or at least reduces a threshold voltage shift of a transistor included in a pixel during a process of repairing a defective pixel using a laser and a repair method thereof.

Still another aspect of the present disclosure is to provide a display device in which a repair process of a defective pixel is minimized, or at least reduced, and a repair method thereof.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device display device may comprise a substrate; a pixel on the substrate, the pixel including a pixel circuit connected between a first power line configured to supply a first power voltage and a second power line configured to supply a second power voltage, and a light emitting element connected to the pixel circuit; a welding electrode on the substrate; a first auxiliary line having one end connected to at least one node connected to the pixel circuit and the other end disposed to be connectable to the welding electrode; and a second auxiliary line having one end connected to the welding electrode and the other end connected to the second power line.

In another aspect, a display device may comprise a substrate on which a plurality of unit pixels each including a plurality of subpixels is defined; a first power line configured to supply a first power voltage to each of the plurality of subpixels; and a second power line configured to supply a second power voltage to each of the plurality of subpixels, wherein each of the plurality of subpixels includes a pixel circuit on the substrate, the pixel circuit connected between the first power line and the second power line; a light emitting element and connected to the pixel circuit; a welding electrode on the substrate; and a pad electrode electrically connected to the second power line and having a portion partially exposed to electrically connect to a cathode electrode of the light emitting element, wherein one end of the welding electrode is electrically connected to either at least one node of the pixel circuit or the second power lines, and the other end of the welding electrode is disposed to be connectable to the other one of the at least one node or the second power line.

In another aspect, a repair method of a display device including a substrate; a pixel on the substrate and having a pixel circuit connected between a first power line configured to provide a first power voltage and a second power line configured to provide a second power voltage, and a light emitting element connected to the pixel circuit; a welding electrode on the substrate; a first auxiliary line having one end connected to at least one node connected to the pixel circuit and the other end disposed to be connectable to the welding electrode; and a second auxiliary line having one end connected to the welding electrode and the other end connected to the second power line, the repair method may comprise a step of electrically connecting the first auxiliary line and the welding electrode through a laser welding process when the pixel is a defective pixel.

In another aspect, a display device may comprise a substrate; a pixel on the substrate, the pixel including: a pixel circuit connected between a first power line configured to supply a first power voltage and a second power line configured to supply a second power voltage, and a light emitting element connected to the pixel circuit; a welding electrode on the substrate; an insulating layer on the welding electrode; a first auxiliary line having a first end thereof connected to the pixel circuit and a second end thereof over the welding electrode with the insulating layer therebetween; and a second auxiliary line having a first end thereof over the welding electrode with the insulating layer therebetween and a second end thereof connected to the second power line, wherein one of the first auxiliary line and the second auxiliary line is connected to the welding electrode through the insulating layer.

In an example embodiment of the present disclosure, a repair process for a defective pixel may be performed through a laser welding process for an auxiliary line or a welding electrode connected to at least one node connected to a pixel circuit.

In addition, because the pad electrode for the repair process according to an example embodiment of the present disclosure is disposed between adjacent pixels, even if a laser is irradiated on a welding point in the repair process, the laser is shielded by the pad electrode to prevent the laser from being irradiated to a normal pixel adjacent to a defective pixel.

Accordingly, the threshold voltage shift of the transistor included in the normal pixel that may occur during the repair process may be prevented.

Further, unlike related art defective pixel repair processes, a repair process in accordance with an example embodiment of the present disclosure, only a laser welding process for connecting the auxiliary line to the welding electrode is performed to repair the defective pixel so that the repair process may be minimized or at least reduced.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view schematically illustrating a display device according to an example embodiment of the present disclosure.

FIG. 2 is a circuit diagram illustrating an example of a pixel included in a display device of FIG. 1.

FIG. 3 is a cross-sectional view illustrating a display device according to an example embodiment of the present disclosure.

FIG. 4 is an enlarged plan view illustrating an example of a display panel included in a display device according to an example embodiment of the present disclosure.

FIG. 5 is a cross-sectional view illustrating an example along the line I-I′ of FIG. 4.

FIGS. 6 and 7 are views for explaining an example of a defective pixel repair process of a display device according to an example embodiment of the present disclosure.

FIG. 8 is a view for explaining another example of a defective pixel repair process of a display device according to an example embodiment of the present disclosure.

FIG. 9 is a view for explaining another example of a defective pixel repair process of a display device according to an example embodiment of the present disclosure.

FIG. 10 is a schematic enlarged plan view of a display panel included in a display device according to another example embodiment of the present disclosure.

FIG. 11 is a cross-sectional view illustrating an example taken along line II-II′ of FIG. 10.

FIG. 12 is a schematic enlarged plan view of a display panel included in a display device according to still another example embodiment of the present disclosure.

FIG. 13 is a schematic enlarged plan view of a display panel included in a display device according to still another example embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on”, “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to the drawings.

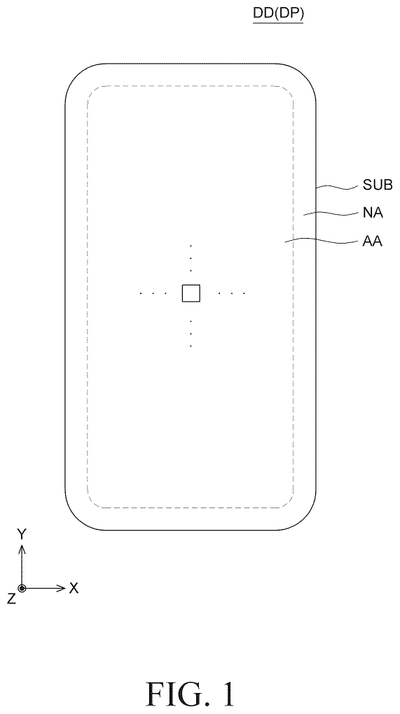

FIG. 1 is a plan view schematically illustrating a display device according to an example embodiment of the present disclosure.

With reference to FIG. 1, the display device DD may include a display panel DP, and the display panel DP may include a display area AA and a non-display area NA excluding the display area AA. The display area AA may be defined as an area in which an image is displayed. For example, the display panel DP may include a substrate SUB and a plurality of pixels PX disposed in the display area AA of the substrate SUB.

One pixel PX may include a plurality of subpixels emitting light of different colors. For example, one pixel PX may implement blue, red, and green colors using three subpixels. However, the present disclosure is not limited thereto, and in some cases, the pixel PX may further include a subpixel for further implementing a specific color, for example, white. In the pixel PX, an area implementing blue may be referred to as a blue subpixel, an area implementing red may be referred to as a red subpixel, and an area implementing green may be referred to as a green subpixel.

The display device DD may display an image through the display area AA. The display surface defined by the display area AA may be parallel to a surface defined by a first direction axis, for example, an axis extending in the first direction X and an axis extending in the second direction axis, for example, in the second direction Y. A normal direction of the display surface, for example, a thickness direction of the display device DD may be defined as a third direction Z.

Front surfaces (or top surfaces) and rear surfaces (or bottom surfaces) of the members or units of the display device DD to be described below may be distinguished from each other along the third direction Z. However, the first direction X, the second direction Y, and the third direction Z illustrated in the present disclosure are only examples, and the first direction X, the second direction Y, and the third direction Z are relative concepts and may be converted into other directions. Hereinafter, for convenience of description, the same reference numerals refer to the first direction X, the second direction Y, and the third direction Z, respectively. Meanwhile, in accordance with the present disclosure, when expressed as “overlapping,” two configurations may overlap in the thickness direction of the display device DD, for example, in the third direction Z, unless otherwise defined.

Meanwhile, FIG. 1 illustrates that the display device DD, for example, the display panel DP included in the display device DD, has a rounded shape at a corner at which one long side and one short side intersect, but this is just illustrative, and the shape of the display panel DP is not limited thereto. For example, the display panel DP may have an angled shape at a corner where one long side and one short side intersect.

In an embodiment, the display panel DP may include a flat display area AA, but is not limited thereto. For example, the display panel DP may include a curved display area or a three-dimensional display area.

Meanwhile, the display area AA is not only used as an area for displaying an image, but also may be used as an area for recognizing a user's touch input, for example, a sensing area or a touch area. In this case, the display device DD may further include a touch sensor. The non-display area NA may be defined as an area in which no image is displayed. The non-display area NA may be disposed to surround or to be adjacent and/or to be outside of the display area AA, but is not limited thereto.

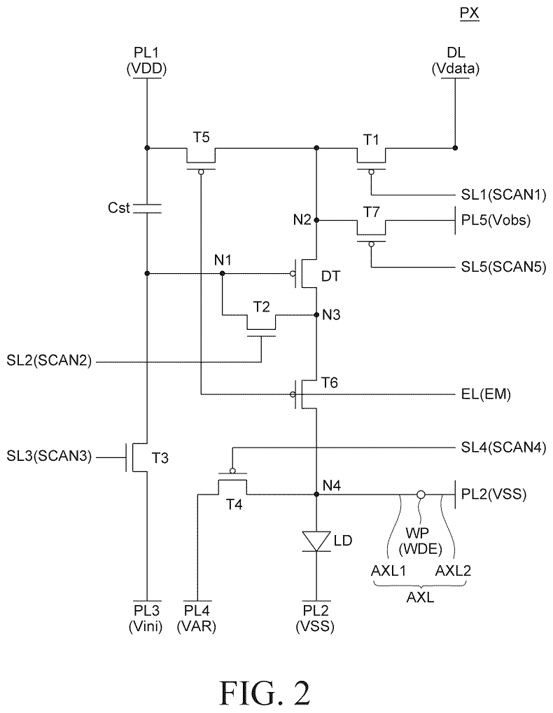

FIG. 2 is a circuit diagram illustrating an example of a pixel included in a display device of FIG. 1. Meanwhile, the pixel PX illustrated in FIG. 2 represents an embodiment of the pixel PX included in the display panel DP of the display device DD that has been described with reference to FIG. 1.

With reference to FIG. 2, the pixel PX may include a light emitting element LD and a pixel circuit. The pixel circuit of the pixel PX is connected between the first power line PL1 and the second power line PL2 to control the light emitting element LD and may include a driving transistor DT, a plurality of transistors T1 to T7, and a storage capacitor Cst.

In an embodiment, the driving transistor DT, the first transistor T1, the fourth transistor T4, the fifth transistor T5, the sixth transistor T6, and the seventh transistor T7 may be formed of polysilicon semiconductor transistors. For example, the driving transistor DT, the first transistor T1, the fourth transistor T4, the fifth transistor T5, the sixth transistor T6, and the seventh transistor T7 may include a polysilicon semiconductor layer formed through a low temperature polysilicon (LTPS) process as an active layer (channel). In addition, the driving transistor DT, the first transistor T1, the fourth transistor T4, the fifth transistor T5, the sixth transistor T6, and the seventh transistor T7 may be P-type transistors, for example, PMOS transistors. Accordingly, the gate-on voltage for turning on the driving transistor DT, the first transistor T1, the fourth transistor T4, the fifth transistor T5, the sixth transistor T6, and the seventh transistor T7 may be at a low logic level.

Because the polysilicon semiconductor transistor has the advantage of fast response speed, the polysilicon semiconductor transistor may be applied to a switching element that requires fast switching. Further, in an embodiment, the second transistor T2 and the third transistor T3 may be formed of an oxide semiconductor transistor. For example, the second transistor T2 and the third transistor T3 may be N-type oxide semiconductor transistors, for example, NMOS transistors, and include an oxide semiconductor layer as an active layer. Accordingly, the gate-on voltage for turning on the second transistor T2 and the third transistor T3 may be at a high logic level.

The oxide semiconductor transistor can be processed at a low temperature and has a lower charge mobility than the polysilicon semiconductor transistor. For example, the oxide semiconductor transistor has excellent off-current characteristics. Accordingly, when the second transistor T2 and the third transistor T3 are formed as oxide semiconductor transistors, leakage current from the third node N3 due to low frequency driving may be minimized or at least reduced, thereby improving display quality.

However, the driving transistor DT and the plurality of transistors T1 to T7 are not limited thereto and at least one of the driving transistor DT, the first transistor T1, the fourth transistor T4, the fifth transistor T5, the sixth transistor T6, and the seventh transistor T7 may be formed of an oxide semiconductor transistor, or at least one of the second transistor T2 and the third transistor T3 may be formed of a polysilicon semiconductor transistor.

The driving transistor DT may include a gate electrode connected between a first power line PL1 configured to provide a first power voltage VDD, for example, a high potential power voltage, and a second power line PL2 configured to provide a second power voltage VSS, for example, a low potential power voltage, and connected to the first node N1. For example, a first electrode, for example, a source electrode, of the driving transistor DT may be connected to the second node N2, and a second electrode, for example, a drain electrode, may be connected to the third node N3.

The driving transistor DT may control a driving current flowing from the first power line PL1 to the second power line PL2 via the light emitting element LD in response to a voltage of the first node N1 corresponding to the gate electrode, for example, an amount of a driving current. To this end, the first power voltage VDD may be set to a voltage higher than the second power voltage VSS. For example, the first power voltage VDD may be a positive voltage, and the second power voltage VSS may be a negative voltage.

According to an example embodiment, each of the first power line PL1 and the second power line PL2 may have a line shape that forms a mesh structure on the display panel DP, but is not limited thereto.

The first transistor T1 may be connected between the data line DL and the second node N2 and may be connected to the first scan line SL1. For example, a first electrode, for example, a source electrode, of the first transistor T1 may be connected to the data line DL, and a second electrode, for example, a drain electrode, may be connected to the second node N2. The first transistor T1 is turned on when the turn-on level of first scan signal SCAN1 is supplied to the first scan line SL1 to electrically connect the data line DL and the second node N2. In this case, the data signal Vdata provided to the data line DL may be provided to the second node N2.

The second transistor T2 may be connected between the gate electrode and the second electrode of the driving transistor DT, for example, between the first node N1 and the third node N3, and may be connected to the second scan line SL2. For example, a first electrode, for example, a source electrode, of the second transistor T2 may be connected to the first node N1, and a second electrode, for example, a drain electrode, may be connected to the third node N3. The second transistor T2 is turned on when the turn-on level of second scan signal SCAN2 is supplied to the second scan line SL2 to electrically connect the gate electrode and the second electrode of the driving transistor DT. In this case, the driving transistor DT may be connected in a diode form.

The third transistor T3 may include a gate electrode connected between the first node N1 and the third power line PL3 configured to provide the initialization voltage Vini and connected to the third scan line SL3. For example, a first electrode, for example, a source electrode, of the third transistor T3 may be connected to the first node N1 corresponding to the gate electrode of the driving transistor DT, and a second electrode, for example, a drain electrode, may be connected to the third power line PL3. The third transistor T3 is turned on when the turn-on level of third scan signal SCAN3 is supplied to the third scan line SL3 to supply the initialization voltage Vini to the first node N1, for example, the gate electrode of the driving transistor DT. In this case, the gate electrode of the driving transistor DT may be initialized by the initialization voltage Vini. To this end, the initialization voltage Vini may be set to a voltage lower than the lowest level of the data signal Vdata.

The fourth transistor T4 may include a first electrode of the light emitting element LD, for example, a gate electrode connected between the fourth node N4 and the fourth power line PL4 configured to provide the reset voltage VAR and connected to the fourth scan line SL4. For example, a first electrode, for example, a source electrode, of the fourth transistor T4 may be connected to the fourth power line PL4, and a second electrode, for example, a drain electrode, may be connected to the fourth node N4. The fourth transistor T4 is turned on when the turn-on level of fourth scan signal SCAN4 is supplied to the fourth scan line SL4 to supply the reset voltage VAR to the fourth node N4, for example, the first electrode of the light emitting element LD. In this case, the parasitic capacitor of the light emitting element LD may be discharged by the reset voltage VAR. Unintentional microluminescence may be prevented as the residual voltage charged in the parasitic capacitor is discharged (removed). Accordingly, the ability of the pixel PX to express black may be improved.

The fifth transistor T5 may include a gate electrode connected between the first power line PL1 and a first electrode of the second node N2, for example, the driving transistor DT, and connected to the emission control line EL. For example, a first electrode, for example, a source electrode, of the fifth transistor T5 may be connected to the first power line PL1, and a second electrode, for example, a drain electrode, may be connected to the second node N2. The fifth transistor T5 may be turned on or turned off by the emission control signal EM supplied to the emission control line EL. When the fifth transistor T5 is turned on, the second node N2 may be electrically connected to the first power line PL1.

The sixth transistor T6 may include a gate electrode connected between the third node N3 and the fourth node N4, for example, between the second electrode of the driving transistor DT and the first electrode of the light emitting element LD, and connected to the light emission control line EL. For example, a first electrode, for example, a source electrode, of the sixth transistor T6 may be connected to the third node N3, and a second electrode, for example, a drain electrode, may be connected to the fourth node N4. The sixth transistor T6 may be controlled in substantially the same manner as the fifth transistor T5. When the sixth transistor T6 is turned on, the third node N3 and the fourth node N4 may be electrically connected.

Meanwhile, according to the operations of the fifth transistor T5 and the sixth transistor T6 described above, the turn-on level of emission control signal EM is supplied so that when both the fifth transistor T5 and the sixth transistor T6 are turned on, a current path through which current flows from the first power line PL1 to the light emitting element LD via the driving transistor DT may be formed. Accordingly, the light emitting element LD may emit light in response to the driving current.

Meanwhile, FIG. 2 illustrates that the fifth transistor T5 and the sixth transistor T6 are connected to the same light emission control line EL, but this is illustrative and the embodiment of the present disclosure is not limited thereto. For example, the fifth transistor T5 and the sixth transistor T6 may be connected to separate light emission control lines to which different light emission control signals are supplied.

The seventh transistor T7 may include a gate electrode connected between the second node N2, for example, the first electrode of the driving transistor DT and the fifth power line PL5 configured to provide the bias voltage Vobs, and connected to the fifth scan line SL5. For example, a first electrode, for example, a source electrode, of the seventh transistor T7 may be connected to the fifth power line PL5, and a second electrode, for example, a drain electrode, may be connected to the second node N2. The seventh transistor T7 is turned on when the turn-on level of fifth scan signal SCAN5 is supplied to the fifth scan line SL5 to supply the bias voltage Vobs to the second node N2.

In an embodiment, the bias voltage Vobs may have a level similar to the voltage level of the data signal Vdata having the black gray scale. For example, the bias voltage Vobs may have a voltage level of about 5 to 7 V, but is not limited thereto.

Accordingly, a predetermined high voltage may be applied to the first electrode of the driving transistor DT by the turn-on of the seventh transistor T7. Here, when the second transistor T2 is in a turn-off state, the driving transistor DT may have an on-bias state (i.e., on-bias state). Here, as the bias voltage Vobs is periodically supplied to the second node N2, the bias state of the driving transistor DT may be periodically changed, and the threshold voltage characteristic of the driving transistor DT may be changed. Accordingly, in the low frequency driving, the characteristics of the driving transistor DT are fixed to a specific state and deterioration may be prevented.

According to an embodiment, the fifth scan signal SCAN5 may correspond to the third scan signal SCAN3 supplied to the previous pixel row. For example, the fifth scan line SL5 may be a third scan line SL3 disposed in a previous pixel row, but is not limited thereto.

The storage capacitor Cst may be connected between the first power line PL1 and the first node N1. As one electrode of the storage capacitor Cst is connected to the first power line PL1 to which the first power voltage VDD, which is a constant voltage, is supplied, the voltage of the first node N1 may be maintained at the voltage level of the voltage supplied directly to the first node N1 without being affected by other parasitic capacitors. For example, the storage capacitor Cst may store the voltage applied to the first node N1.

The first electrode, for example, the anode electrode of the light emitting element LD may be connected to the fourth node N4 and the second electrode, for example, the cathode electrode, may be connected to the second power line PL2. The light emitting element LD may generate light having a predetermined luminance in response to a driving current supplied from the driving transistor DT. The light emitting element LD may be a discrete semiconductor LED or an organic LED.

Meanwhile, FIG. 2 illustrates that the pixel PX has a pixel circuit structure including eight transistors and one capacitor. However, this is provided for illustrative purposes only. The pixel PX may include an additional transistor and/or a capacitor, and/or the pixel circuit structure may include a pixel circuit structure in which at least one of the transistor and the capacitor illustrated in FIG. 2 is omitted.

In an embodiment, the auxiliary line AXL may be connected to at least one node connected to the pixel circuit included in the pixel PX, for example, at least one node on the current path of the driving current described above. For example, the auxiliary line AXL may be electrically connected to the fourth node N4 corresponding to the light emitting element LD, for example, the anode electrode that is the first electrode of the light emitting element LD.

The auxiliary line AXL may include a first auxiliary line AXL1 disposed between the fourth node N4 and the welding point WP and a second auxiliary line AXL2 disposed between the welding point WP and the second power line PL2.

Here, the welding point WP is a point where welding is performed through a laser welding process using a laser during repair of a defective pixel. When the pixel PX is determined as a defective pixel and a repair process is performed for the corresponding pixel PX, the welding point WP is welded using a laser to electrically connect the first auxiliary line AXL1 and the second auxiliary line AXL2.

For example, a welding electrode WDE, which is a structure connectable to the first auxiliary line AXL1 and the second auxiliary line AXL2, may be disposed at the welding point WP. For example, the welding electrode WDE may be electrically connected to the second auxiliary line AXL2 and may be disposed to be connected to the first auxiliary line AXL1.

Meanwhile, in the present disclosure, the term “connectable or connectable” may mean a state that may be connected using a laser or the like during a repair process.

For example, the fact that the welding electrode WDE is disposed to be connectable to the first auxiliary line AXL1 may mean that the welding electrode WDE and the first auxiliary line AXL1 are electrically insulated without performing the repair process, but when the repair process is performed, the welding electrode WDE and the first auxiliary line AXL1 are electrically connected to each other by welding of the welding point WP. For example, in a state in which the repair process is not performed, the welding electrode WDE and the first auxiliary line AXL1 are disposed so that at least a part of the welding electrode WDE and the first auxiliary line AXL1 overlap at the welding point WP with at least one insulating layer therebetween. When the repair process is performed, when the welding point WP is irradiated with laser beams, the welding electrode WDE and the first auxiliary line AXL1 may be electrically connected (for example, electrically short-circuited) as the at least one insulating layer in the corresponding welding point WP is destroyed.

Accordingly, in a state in which the repair process is not performed on the pixel PX, the first auxiliary line AXL1 and the second auxiliary line AXL2 may be electrically opened, and when the repair process is performed because the pixel PX is determined as a defective pixel, the first auxiliary line AXL1 and the second auxiliary line AXL2 may be electrically connected to each other by the welding electrode WDE.

In this case, in the corresponding pixel PX that is a defective pixel, the driving current does not flow to the light emitting element LD, but flows to the second power line PL2 through the auxiliary line AXL, for example, the first auxiliary line AXL1 and the second auxiliary line AXL2, so that the light emitting element LD does not emit light, and the corresponding pixel PX may be darkened. Accordingly, the corresponding pixel PX, which is a defective pixel, may be repaired.

However, the embodiment of the present disclosure is not limited thereto. For example, the welding electrode may be connected to the first auxiliary line AXL1 and may be disposed to be connected to the second auxiliary line AXL2. As another example, the welding electrode may be disposed to be connected to each of the first auxiliary line AXL1 and the second auxiliary line AXL2.

Meanwhile, FIG. 2 illustrates a structure in which the first auxiliary line AXL1, the welding electrode WDE, and the second auxiliary line AXL2 are disposed between the fourth node N4 and the second power line PL2 to be electrically connected, but some components may be omitted. For example, the first auxiliary line AXL1 and the second auxiliary line AXL2 may be omitted and only the welding electrode WDE may be disposed between the fourth node N4 and the second power line PL2. In this case, the welding electrode WDE may be electrically connected to the fourth node N4 and may be disposed to be connected to the second power line PL2.

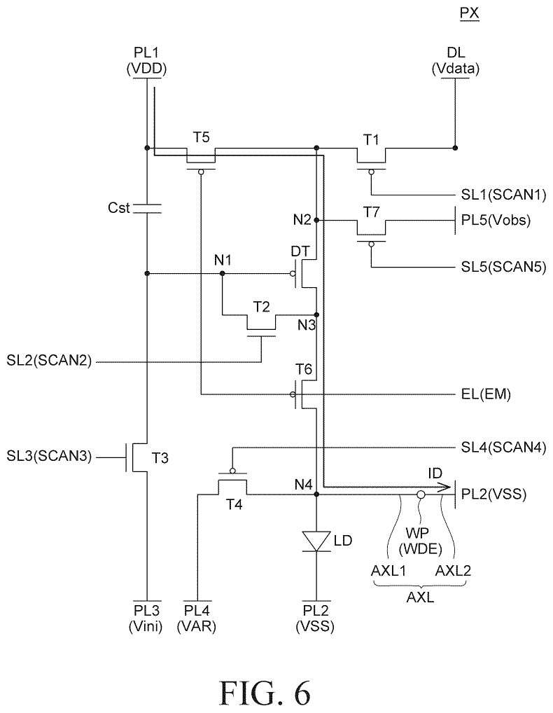

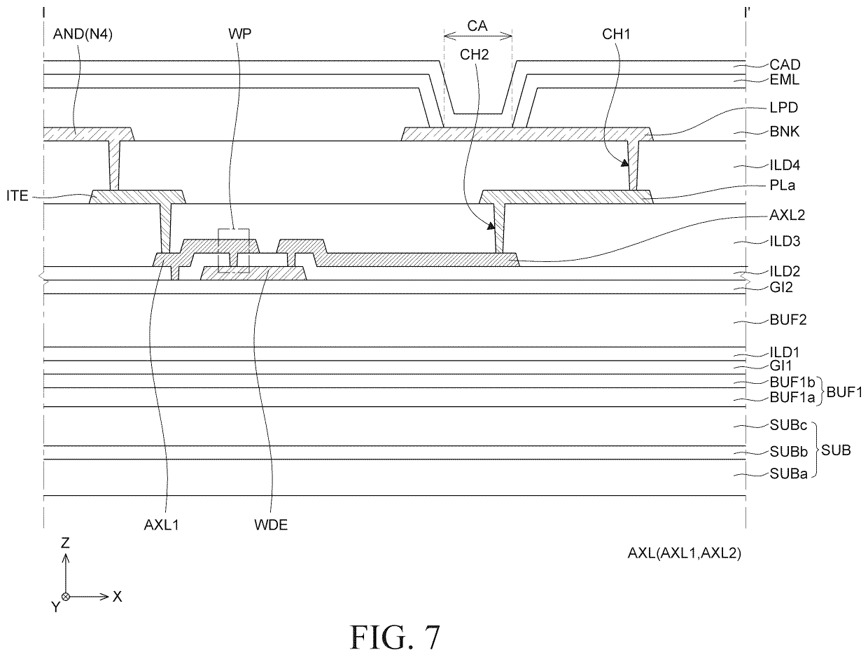

A more detailed description of the repair process of the pixel PX will be described in detail with reference to FIGS. 6 and 7.

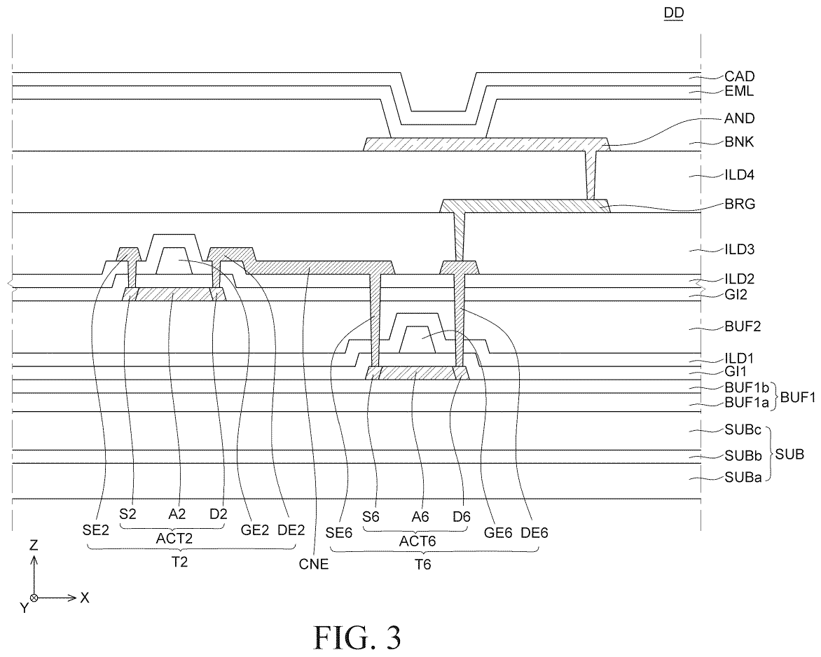

FIG. 3 is a cross-sectional view illustrating a display device according to an example embodiment of the present disclosure. For example, FIG. 3 illustrates a cross-sectional view illustrating an example of a pixel PX included in the display device DD. For convenience of description, FIG. 3 exemplarily illustrates a second transistor T2, a sixth transistor T6, and a light emitting element LD among various components included in the pixel PX described with reference to FIG. 2.

With reference to FIG. 3, the second transistor T2, the sixth transistor T6, and the light emitting element LD may be disposed on the substrate SUB.

The substrate SUB is a base material of the display panel DP and may be a substantially transparent light-transmitting substrate. The substrate SUB may be a flexible substrate made of a plastic material. For example, the substrate SUB may include polyimide (PI). Meanwhile, when the substrate SUB includes polyimide (PI), moisture penetrates through the substrate SUB made of polyimide (PI) and penetrates into a thin film transistor included in the pixel PX, thereby reducing the reliability of the pixel PX, which may degrade the performance of the display device DD.

Accordingly, in an embodiment, the substrate SUB may include double polyimide (PI). Further, the substrate SUB further includes an inorganic film formed between the two polyimides (PI) so that the reliability of the product performance may be further improved by blocking the moisture component from passing through the lower polyimide (PI). In addition, an inorganic film is formed between the two polyimides (PI) to block charges charged in the lower polyimide (PI), thereby further improving the reliability of the product.

For example, as illustrated in FIG. 3, the substrate SUB may include a first sub substrate SUBa including polyimide (PI), a second sub substrate SUBb disposed on the first sub substrate SUBa and including an inorganic insulating material, and a third sub substrate SUBc disposed on the second sub substrate SUBb and including polyimide (PI). Meanwhile, this is an example, and the substrate SUB may be a rigid substrate including glass or tempered glass.

The first buffer layer BUF1 may be disposed on the substrate SUB. The first buffer layer BUF1 may serve to improve adhesion between components formed thereon and the substrate SUB and block moisture or oxygen permeating through the substrate SUB. For example, the first buffer layer BUF1 may include a multi-buffer layer BUF1a disposed on the substrate SUB and an active buffer layer BUF1b disposed on the multi-buffer layer BUF1a, but is not limited thereto.

The sixth transistor T6 may be disposed on the first buffer layer BUF1. For example, the semiconductor pattern ACT6, the gate electrode GE6, the source electrode SE6, and the drain electrode DE6 of the sixth transistor T6 may be disposed on the first buffer layer BUF1.

A first semiconductor layer may be disposed on the first buffer layer BUF1. For example, the first semiconductor layer is a semiconductor layer including polysilicon, and may form semiconductor patterns of the driving transistor DT, the first transistor T1, the fourth transistor T4, the fifth transistor T5, the sixth transistor T6, and the seventh transistor T7 described with reference to FIG. 2.

For example, the semiconductor pattern ACT6 of the sixth transistor T6 may be disposed on the first buffer layer BUF1. The semiconductor pattern ACT6 of the sixth transistor T6 may include a first region S6, a second region D6, and a channel region A6 therebetween. For example, each of the first region S6 and the second region D6 may be a source region and a drain region of the semiconductor pattern ACT6.

A first gate insulating layer GI1 may be disposed on the first buffer layer BUF1. For example, the first gate insulating layer GI1 may be disposed on the first buffer layer BUF1 to cover the semiconductor pattern ACT6 of the first semiconductor layer, for example, the sixth transistor T6, to insulate the semiconductor pattern ACT6 of the sixth transistor T6 and the gate electrode GE6.

The gate electrode GE6 of the sixth transistor T6 may be disposed on the first gate insulating layer GI1. For example, the gate electrode GE6 of the sixth transistor T6, which constitutes at least a part of the light emission control line EL, may be disposed on the first gate insulating layer GI1. The gate electrode GE6 of the sixth transistor T6 may be disposed to overlap at least a portion of the semiconductor pattern ACT6.

A first insulating layer ILD1 may be disposed on the first gate insulating layer GI1. For example, the first insulating layer ILD1 may be disposed on the first gate insulating layer GI1 to cover the gate electrode GE6 of the sixth transistor T6.

A second buffer layer BUF2 may be disposed on the first insulating layer ILD1. The second buffer layer BUF2 may planarize an upper portion and cover components disposed therebelow.

The second transistor T2 may be disposed on the second buffer layer BUF2. For example, the semiconductor pattern ACT2, the gate electrode GE2, the source electrode SE2, and the drain electrode DE2 of the second transistor T2 may be disposed on the second buffer layer BUF2.

A second semiconductor layer may be disposed on the second buffer layer BUF2. For example, the second semiconductor layer is a semiconductor layer including an oxide semiconductor and may form semiconductor patterns of the second transistor T2 and the third transistor T3 described with reference to FIG. 2.

For example, the semiconductor pattern ACT2 of the second transistor T2 may be disposed on the second buffer layer BUF2. The semiconductor pattern ACT2 of the second transistor T2 may include a first region S2, a second region D2, and a channel region A2 therebetween. For example, each of the first region S2 and the second region D2 may be a source region and a drain region of the semiconductor pattern ACT2.

A second gate insulating layer GI2 may be disposed on the second buffer layer BUF2. For example, the second gate insulating layer GI2 may be disposed on the second buffer layer BUF2 to cover the semiconductor pattern ACT2 of the second semiconductor layer, for example, the second transistor T2, to insulate the semiconductor pattern ACT2 of the second transistor T2 and the gate electrode GE2.

The gate electrode GE2 of the second transistor T2 may be disposed on the second gate insulating layer GI2. For example, the gate electrode GE2 of the second transistor T2, which constitutes at least a part of the scan line, for example, the second scan line SL2, may be disposed on the second gate insulating layer GI2. The gate electrode GE2 of the second transistor T2 may be disposed to overlap at least a portion of the semiconductor pattern ACT2.

A second insulating layer ILD2 may be disposed on the second gate insulating layer GI2. For example, the second insulating layer ILD2 may be disposed on the second gate insulating layer GI2 to cover the gate electrode GE2 of the second transistor T2.

The source electrode SE6 and the drain electrode DE6 of the sixth transistor T6 may be disposed on the second insulating layer ILD2. The source electrode SE6 and the drain electrode DE6 of the sixth transistor T6 may be in contact with the first region S6 and the second region D6 of the semiconductor pattern ACT6 through at least one contact hole penetrating through the second insulating layer ILD2, the second gate insulating layer GI2, the second buffer layer BUF2, the first insulating layer ILD1, and the first gate insulating layer GI1, respectively.

Further, the source electrode SE2 and the drain electrode DE2 of the second transistor T2 may be disposed on the second insulating layer ILD2. The source electrode SE2 and the drain electrode DE2 of the second transistor T2 may be in contact with the first region S2 and the second region D2 of the semiconductor pattern ACT2 through at least one contact hole penetrating through the second insulating layer ILD2 and the second gate insulating layer GI2, respectively.

Further, the connection electrode CNE may be disposed on the second insulating layer ILD2. The connection electrode CNE may be connected to the sixth transistor T6, for example, the source electrode SE6 of the sixth transistor T6. Here, any one of the source electrode SE2 and the drain electrode DE2 of the second transistor T2, for example, the drain electrode DE2 of the second transistor T2 may be electrically connected to the connection electrode CNE. For example, the drain electrode DE2 of the second transistor T2, the connection electrode CNE, and the source electrode SE6 of the sixth transistor T6 may be integrally formed. Accordingly, the drain electrode DE2 of the second transistor T2 may be electrically connected to the source electrode SE6 of the sixth transistor T6.

A third insulating layer ILD3 may be disposed on the second insulating layer ILD2. For example, the third insulating layer ILD3 may be disposed on the second insulating layer ILD2 to cover the source electrode SE2 and the drain electrode DE2 of the second transistor T2, the source electrode SE6 and the drain electrode DE6 of the sixth transistor T6, and the connection electrode CNE.

The bridge electrode BRG may be disposed on the third insulating layer ILD3. The bridge electrode BRG may be in contact with the sixth transistor T6, for example, the drain electrode DE6 of the sixth transistor T6, through at least one contact hole penetrating through the third insulating layer ILD3.

A fourth insulating layer ILD4 may be disposed on the third insulating layer ILD3. For example, the fourth insulating layer ILD4 may be disposed on the third insulating layer ILD3 to cover the bridge electrode BRG. The fourth insulating layer ILD4 may be an organic layer for planarizing an upper portion and protecting components disposed therebelow.

The light emitting element LD may be disposed on the fourth insulating layer ILD4. The light emitting element LD includes a first electrode and a second electrode, for example, an anode electrode AND and a cathode electrode CAD, and may include an emission layer EML formed therebetween.

The anode electrode AND may be disposed on the fourth insulating layer ILD4. The anode electrode AND may be connected to the bridge electrode BRG through a through hole which passes through the fourth insulating layer ILD4 to expose at least a part of the bridge electrode BRG. Accordingly, the anode electrode AND may be connected to the drain electrode DE6 of the sixth transistor T6 through the bridge electrode BRG.

The bank layer BNK may be disposed to cover at least a part of the anode electrode AND and may open the remaining part of the anode electrode AND. For example, the bank layer BNK may be disposed so that a portion corresponding to the emission area of the pixel PX is opened. Accordingly, a part of the anode electrode AND may be exposed by the open part of the bank layer BNK.

The emission layer EML may be disposed on the front surface of the pixel PX on top surfaces of the bank layer BNK and the anode electrode AND. Meanwhile, a part of the emission layer EML may be in contact with the exposed part of the anode electrode AND by the open part of the bank layer BNK.

The cathode electrode CAD may be disposed on the emission layer EML. For example, at least a part of the second power line PL2 that supplies the second power voltage VSS to the pixel PX may constitute the cathode electrode CAD of the light emitting element LD. The light emitting element LD may be formed by the anode electrode AND, the emission layer EML, and the cathode electrode CAD. Meanwhile, although not separately shown in FIG. 3, an encapsulation layer may be further disposed on the light emitting element LD.

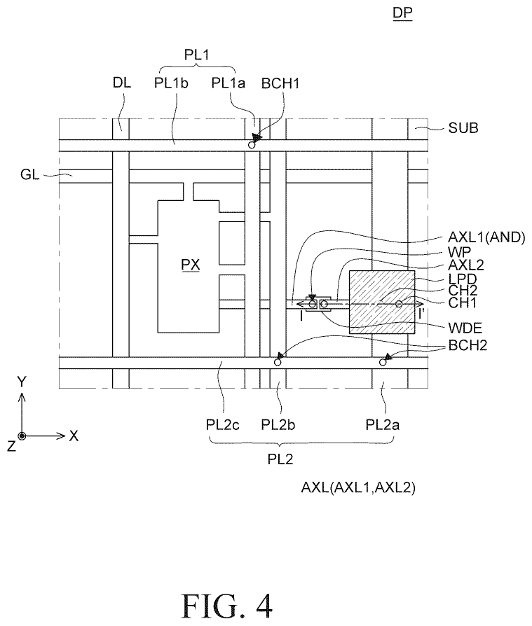

FIG. 4 is an enlarged plan view illustrating an example of a display panel included in a display device according to an example embodiment of the present disclosure. For example, FIG. 4 is an enlarged plan view illustrating a part of the display panel DP included in the display device DD described with reference to FIGS. 1 to 3, and shows an example of one pixel PX and lines connected thereto.

With reference to FIG. 4, the display panel DP may include a pixel PX and a data line DL, a gate line GL, a first power line PL1, and a second power line PL2 connected to the pixel PX. Meanwhile, the gate line GL illustrated in FIG. 4 may be any one of the plurality of scan lines SL1 to SL5 and the emission control line EL described with reference to FIG. 2.

Each of the plurality of pixels PX may be disposed in an area where the gate line GL and the data line DL intersect. The gate lines GL may be disposed on the substrate SUB, extend in the first direction X, and spaced apart from each other at regular intervals in the second direction Y. The data line DL may be disposed on the substrate SUB, extend in the second direction Y, and spaced apart at regular intervals in the first direction X.

Each of the plurality of pixels PX may be connected to the gate line GL and the data line DL. For example, each of the plurality of pixels PX may be connected to the gate line GL and the data line DL by a line branched in the second direction Y from the gate line GL extending in the first direction X and a line branched in the first direction X from the data line DL extending in the second direction Y.

The first power line PL1 and the second power line PL2 may be disposed on the substrate SUB. In an embodiment, each of the first power line PL1 and the second power line PL2 may be disposed to form a mesh structure. For example, each of the first power line PL1 and the second power line PL2 may include at least one sub-power line and at least one power bridge line that are disposed to extend in each of the first direction X and the second direction Y.

For example, the first power line PL1 may include a first sub-power line PL1a and a first power bridge line PL1b connected to the first sub-power line PL1a. The first sub-power line PL1a extends in the second direction Y and may be disposed on one side of the pixel PX along the first direction X, for example, on the right side of the pixel PX. For example, the first sub-power line PL1a may be disposed between two pixels PX adjacent to each other in the first direction X. The pixel PX may be connected to a line branched in the first direction X from the first sub-power line PL1a to receive the first power voltage VDD from the first power line PL1, for example, the first sub-power line PL1a.

The first power bridge line PL1b may be disposed to intersect the first sub-power line PL1a to form a mesh structure of the first power line PL1. For example, the first power bridge line PL1b may extend in the first direction X and may be disposed on one side of the pixel PX along the second direction Y, for example, on the upper side of the pixel PX. For example, the first power bridge line PL1b may be disposed between two pixels PX adjacent to each other in the second direction Y.

The first power bridge line PL1b may be electrically connected to the first sub-power line PL1a through at least one first bridge contact hole BCH1. At least one first bridge contact hole BCH1 may be formed to correspond to a position where the first power bridge line PL1b and the first sub power line PL1a overlap or intersect. Further, the second power line PL2 may include a second sub-power line PL2a, a third sub-power line PL2b, and a second power bridge line PL2c connected to the second sub-power line PL2a and the third sub-power line PL2b.

The second sub-power line PL2a and the third sub-power line PL2b may be disposed to be spaced apart from each other in the first direction X. Each of the second sub-power line PL2a and the third sub-power line PL2b may extend in the second direction Y and may be disposed on one side of the pixel PX along the first direction X, for example, on the right side of the pixel PX. For example, each of the second sub-power line PL2a and the third sub-power line PL2b may be disposed between two pixels PX adjacent to each other in the first direction X. For example, the first sub-power line PL1a may be disposed between the pixel PX and the second sub-power line PL2a. The pixel PX may be connected to a line line branched in the first direction X from the second power line PL2, for example, the third sub power line PL2b, and receive the second power voltage VSS from the third sub power line PL2b.

According to an example embodiment, as illustrated in FIG. 4, a width of the second sub power line PL2a may be larger than a width of the third sub power line PL2b, but is not limited thereto. The second power bridge line PL2c may be disposed to cross the second sub-power line PL2a and the third sub-power line PL2b to form a mesh structure of the second power line PL2. For example, the second power bridge line PL2c may extend in the first direction X and may be disposed on the other side of the pixel PX along the second direction Y, for example, under the pixel PX. For example, the first power bridge line PL1b and the second power bridge line PL2c may be disposed to be spaced apart from each other along the second direction Y with one of the first power bridge line PL1b and the pixel PX interposed therebetween.

The second power bridge line PL2c may be electrically connected to each of the second sub-power line PL2a and the third sub-power line PL2b through a plurality of second bridge contact holes BCH2. The plurality of second bridge contact holes BCH2 may be formed to correspond to positions where the second power bridge line PL2c overlaps or intersects the second sub power line PL2a and the third sub power line PL2b, respectively.

As described above, each of the first power line PL1 and the second power line PL2 is formed in a mesh structure on the substrate SUB of the display panel DP to reduce the panel load and minimize, or at least reduce, a voltage drop of the first power voltage VDD provided through the first power line PL1 and the second power voltage VSS provided through the second power line PL2. Accordingly, the display device DD may be driven at low power, thereby reducing power consumption and improving display quality.

According to an example embodiment, each of the first power bridge line PL1b of the first power line PL1 and the second power bridge line PL2c of the second power line PL2 may include a metal material having a low resistance, such as copper (Cu), silver (Ag), aluminum (Al), or gold (Au). In this case, the aforementioned panel load and voltage drop may be further improved.

The display device DD, for example, the display panel DP may further include a pad electrode LPD disposed above the second power line PL2. For example, the pad electrode LPD may be disposed on the second sub-power line PL2a. Therefore, the second sub-power line PL2a may be disposed between the pad electrode LPD and the substrate SUB.

In an embodiment, the pad electrode LPD may be disposed between adjacent pixels PX. For example, the pad electrode LPD may be disposed between adjacent subpixels along the first direction X.

The pad electrode LPD may mitigate a voltage drop in which a potential difference formed in the light emitting element in the pixel decreases. For example, in the case of a large-area display device, the voltage drop is severely generated as the distance from the VSS voltage supply pad unit that applies the second power voltage VSS to the cathode increases, which may cause a problem of non-uniform luminance of the display device. The pad electrode LPD is connected to the second sub power line PL2a, which applies the second power voltage VSS, as an auxiliary electrode, and is electrically connected to the cathode in an arbitrary area of the display area, thereby alleviating the voltage drop.

Meanwhile, the pad electrode LPD may be electrically connected to the auxiliary line AXL disposed to extend in the first direction X. For example, as described with reference to FIG. 2, the auxiliary line AXL may include a first auxiliary line AXL1 connected to the pixel circuit included in the pixel PX with a welding point WP interposed therebetween, and a second auxiliary line AXL2 connected to the pad electrode LPD. The first auxiliary line AXL1 and the second auxiliary line AXL2 are electrically insulated from each other without performing the repair process by the welding electrode WDE, which is a connectable structure, and may be electrically connected to each other when the repair process is performed.

Also, the pad electrode LPD may be connected to the second auxiliary line AXL2. For example, one end of the second auxiliary line AXL2 overlaps the second sub-power line PL2a and may be electrically connected to each other through at least one contact hole CH2. Further, the other end of the second auxiliary line AXL2 overlaps at least a part of the welding electrode WDE and may be connected to the welding electrode WDE through at least one contact hole.

The welding electrode WDE may be disposed to not overlap the first power line PL1 and the second power line PL2. For example, the welding electrode WDE may be disposed between the second sub-power line PL2a and the third sub-power line PL2b and disposed not to overlap each of the second sub-power line PL2a and the third sub-power line PL2b.

In one example embodiment, one end of the first auxiliary line AXL1 is electrically connected to the pixel PX, for example, the anode electrode AND of the pixel PX, and the other end of the first auxiliary line AXL1 may overlap the welding electrode WDE at least partially, for example, on the welding point WP. Accordingly, when the repair process of irradiating the welding electrode WDE, which is the connectable structure, on the welding point WP, with laser beams is performed, the first auxiliary line AXL1 and the welding electrode WDE may be electrically connected to each other.

In an embodiment, when the laser is irradiated onto the welding point WP by the repair process, the laser may be irradiated from top to bottom, for example, in a direction opposite to the third direction Z with respect to the welding point WP. Here, when a metal layer or an electrode layer other than the welding electrode WDE and the first auxiliary line AXL1 is disposed at a position overlapping the welding point WP, a short circuit of the metal layer or the electrode layer may occur. Therefore, the welding point WP may be disposed so as not to overlap another metal layer or electrode layer. For example, the welding point WP may be disposed so as not to overlap the first power line PL1 and the second power line PL2. For example, the welding point WP may be disposed between the second sub-power line PL2a and the third sub-power line PL2b and disposed not to overlap each of the second sub-power line PL2a and the third sub-power line PL2b.

In the meantime, even though in FIG. 4, it is described that the pad electrode LPD is formed between adjacent pixels PX so that the pixel PX and the corresponding pad electrode LPD may be connected to each other through the auxiliary line AXL and the welding electrode WDE, the embodiment of the present disclosure is not limited thereto. For example, the pad electrode LPD may be formed between two pixels PX. In this case, the welding electrode WDE and the auxiliary line AXL are disposed between one pixel PX and the corresponding pad electrode LPD to connect one pixel PX and the corresponding pad electrode LPD, and an additional welding electrode WDE and an additional auxiliary line AXL are disposed between the other pixel PX and the corresponding pad electrode LPD to connect the other pixel PX and the corresponding pad electrode LPD. For example, between each of the two pixels PX and one pad electrode LPD, two welding electrodes WDE corresponding to each of the two welding points WP that do not overlap each other are disposed, and each of the two pixels PX may be formed to be independently connected to the pad electrode LPD through the two welding electrodes WDE and the auxiliary line AXL that overlap different welding points WP.

However, the present disclosure is not limited thereto, and the pad electrode LPD may be formed between three or more pixels PX.

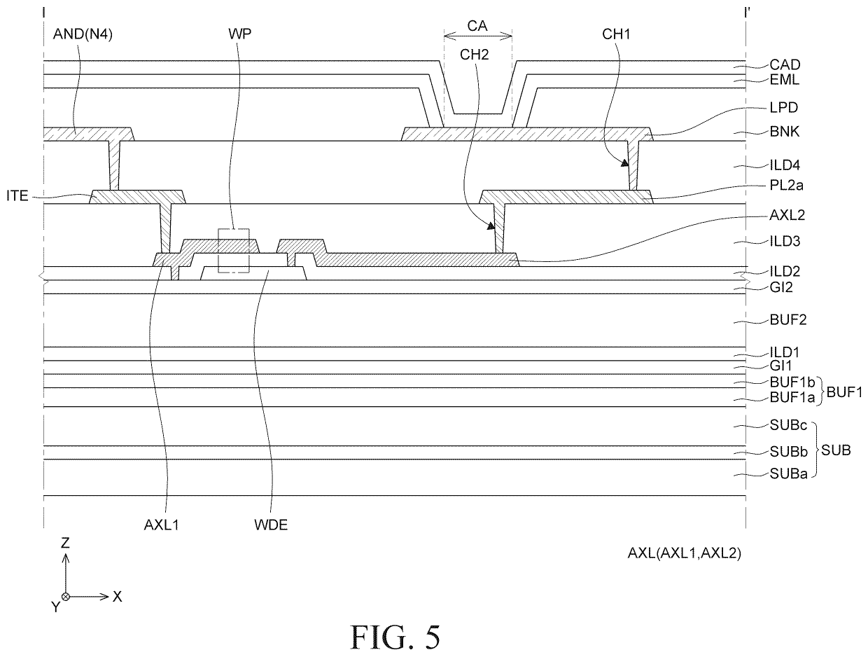

FIG. 5 is a cross-sectional view illustrating an example along the line I-I′ of FIG. 4. For example, FIG. 5 shows an example of a cross-sectional structure according to a state in which the welding electrode WDE, which is a connectable structure, and the first auxiliary line AXL1 are electrically insulated, for example, a state in which a repair process for the corresponding pixel PX is not performed. Meanwhile, for convenience of description, in FIG. 5, repetitive descriptions of the contents described with reference to FIG. 3 will not be repeated.

With reference to FIG. 5, the welding electrode WDE may be electrically connected to the second auxiliary line AXL2 and may be formed of a metal structure connectable to the first auxiliary line AXL1.

For example, the first auxiliary line AXL1 may connect the intermediate electrode ITE and the welding electrode WDE connected to the anode electrode AND of the fourth node N4. Accordingly, the first auxiliary line AXL1 may be electrically connected to the anode electrode AND and connected to the welding electrode WDE. Further, the second auxiliary line AXL2 connects the second sub power line PL2a, which provides the second power voltage VSS, and the welding electrode WDE. Here, the second auxiliary line AXL2 may be electrically connected to the pad electrode LPD through the second sub-power line PL2a.

Accordingly, depending on whether there is a repair process, the anode electrode AND connected to at least one node, for example, the fourth node N4, included in the pixel circuit of the pixel PX through the auxiliary line AXL may be connected to the second power line PL2 that supplies the second power voltage VSS. For example, the welding electrode WDE may be disposed on the second gate insulating layer GI2. The welding electrode WDE is a structure connectable to the first auxiliary line AXL1 and/or the second auxiliary line AXL2 and may be disposed and formed between the second gate insulating layer GI2 and the second insulating layer ILD2. For example, the second insulating layer ILD2 may be disposed on the second gate insulating layer GI2 and may be disposed to cover the welding electrode WDE.

In an embodiment, the welding electrode WDE may be disposed on the same layer as the gate electrode of at least one transistor included in the pixel PX. For example, the welding electrode WDE is included in the pixel PX and may be disposed on the same layer as the gate electrode GE2 of the oxide semiconductor transistor, for example, the second transistor T2. For example, the welding electrode WDE includes the same material as the gate electrode GE2 of the second transistor T2 and may be simultaneously formed by the same process.

A first auxiliary line AXL1 and a second auxiliary line AXL2 may be disposed on the second insulating layer ILD2. For example, each of the first auxiliary line AXL1 and the second auxiliary line AXL2 may be disposed to overlap the welding electrode WDE at least in part.

In an embodiment, the first auxiliary line AXL1 may be disposed to be connected to the welding electrode WDE. For example, at the welding point WP, the first auxiliary line AXL1 and the welding electrode WDE may be disposed to be spaced apart from each other with the second insulating layer ILD2 interposed therebetween. In this case, the first auxiliary line AXL1 and the welding electrode WDE may be electrically insulated from each other. Meanwhile, as described above, when the repair process is performed, the first auxiliary line AXL1 and the welding electrode WDE may be electrically connected to each other.

Further, the second auxiliary line AXL2 may be in contact with the welding electrode WDE through at least one contact hole penetrating the second insulating layer ILD2.

In an embodiment, the first auxiliary line AXL1 and the second auxiliary line AXL2 may be disposed on the same layer as the source electrode and/or the drain electrode of at least one transistor included in the pixel PX, respectively. For example, each of the first auxiliary line AXL1 and the second auxiliary line AXL2 is included in the pixel PX and may be disposed on the same layer as the source electrode SE6 and/or the drain electrode DE6 of the polysilicon semiconductor transistor, for example, the sixth transistor T6. For example, each of the first auxiliary line AXL1 and the second auxiliary line AXL2 includes the same material as the source electrode SE6 and/or the drain electrode DE6 of the sixth transistor T6 and may be simultaneously formed by the same process.

The third insulating layer ILD3 may be disposed on the second insulating layer ILD2 to cover the auxiliary line AXL. The intermediate electrode ITE and the second power line PL2 may be disposed on the third insulating layer ILD3. For example, the intermediate electrode ITE may overlap the first auxiliary line AXL1 at least in part, and the second power line PL2 may be disposed to overlap the second auxiliary line AXL2 at least in part.

The intermediate electrode ITE is in contact with the first auxiliary line AXL1 through at least one contact hole penetrating through the third insulating layer ILD3, and the second power line PL2 may be in contact with the second auxiliary line AXL2 through at least one contact hole CH2 penetrating through the third insulating layer ILD3. Accordingly, the intermediate electrode ITE and the first auxiliary line AXL1 are in contact with each other to electrically connect the anode electrode AND and the welding electrode WDE connected to the fourth node N4. Further, the second power line PL2 and the second auxiliary line AXL2 are in contact with each other to electrically connect the pad electrode LPD and the welding electrode WDE.

The fourth insulating layer ILD4 may be disposed on the third insulating layer ILD3 to cover the intermediate electrode ITE and the second power line PL2. The anode electrode AND disposed on the fourth insulating layer ILD4 may be disposed to at least partially overlap the intermediate electrode ITE and may be in contact with the intermediate electrode ITE through at least one contact hole penetrating the fourth insulating layer ILD4.

Meanwhile, FIG. 5 illustrates a structure in which the first auxiliary line AXL1 is connected to the intermediate electrode ITE to electrically connect the anode electrode AND and the welding electrode WDE, but the embodiment of the present disclosure is not limited thereto. For example, the intermediate electrode ITE may be omitted. In this case, the first auxiliary line AXL1 may be disposed on the second insulating layer ILD2, the anode electrode AND may be disposed to overlap the first auxiliary line AXL1 at least in part without a separate intermediate electrode ITE, and may be in contact with the anode electrode AND of the fourth node N4 through at least one contact hole penetrating through the fourth insulating layer ILD4 and the third insulating layer ILD3 at the same time.

As another example, the first auxiliary line AXL1 may be formed on the third insulating layer ILD3. In this case, one end of the first auxiliary line AXL1 may be disposed to overlap the welding electrode WDE on the welding point WP without the separate intermediate electrode ITE, and the other end of the first auxiliary line AXL1 may be disposed to overlap the anode electrode AND to be connected to the welding electrode WDE and the anode electrode AND.

Further, the pad electrode LPD may be disposed on the fourth insulating layer ILD4. The pad electrode LPD may be connected to the second sub-power line PL2a through a through hole CH1 that penetrates the fourth insulating layer ILD4 to expose at least a part of the second sub-power line PL2a. Accordingly, the pad electrode LPD may be electrically connected to the welding electrode WDE through the second auxiliary line AXL2 and the second sub-power line PL2a.

In an embodiment, the pad electrodes LPD may be disposed on the same layer as the anode electrode AND of the light emitting element LD included in the pixel PX. For example, the pad electrode LPD includes the same material as the anode electrode AND and may be simultaneously formed by the same process.

In an embodiment, at least a part of the emission layer EML is removed to expose at least a part of the pad electrode LPD, and a cathode electrode CAD is disposed on the exposed pad electrode LPD to connect the pad electrode LPD and the cathode electrode CAD. For example, in the process of manufacturing the display device DD, for example, the display panel DP, a reflow process for the contact area CA overlapping the pad electrode LPD and at least a part of the light emitting layer EML formed and/or deposited on the front surface of the pixel PX may be performed. In the reflow process, a laser may be irradiated to the emission layer EML overlapping the contact area CA. Accordingly, at least a part of the light emitting layer EML overlapping the contact area CA is removed to expose the pad electrode LPD. Thereafter, when the deposition process of the cathode electrode CAD is performed, the cathode electrode CAD may be connected to the pad electrode LPD at least partially exposed in the contact area CA. Accordingly, the cathode electrode CAD is electrically connected to the second sub-power line PL2a through the pad electrode LPD to apply the second power voltage VSS.

Meanwhile, FIG. 5 illustrates that the second auxiliary line AXL2 is connected to the second sub-power line PL2a to electrically connect the welding electrode WDE and the pad electrode LPD. However, embodiments of the present disclosure are not limited thereto.

For example, the second auxiliary line AXL2 may be formed on the third insulating layer ILD3. In this case, the second auxiliary line AXL2 may be formed to be connected on the same layer as the second sub-power line PL2a. One end of the second auxiliary line AXL2 may be disposed to overlap the welding electrode WDE at least in part, and may be in contact with the welding electrode WDE through at least one contact hole penetrating through the third insulating layer ILD3 and the second insulating layer ILD2 simultaneously.

Meanwhile, FIG. 5 illustrates that the welding electrode WDE is configured to be connected to the anode electrode AND of the pixel PX through the first auxiliary line AXL1 and electrically connected to the pad electrode LPD through the second auxiliary line AXL2. However, the embodiment of the present disclosure is not limited thereto. According to an embodiment, at least one of the first auxiliary line AXL1 and the second auxiliary line AXL2 may be omitted.

For example, in the display device DD, the first auxiliary line AXL1 may be omitted. In this case, at least a part of the welding electrode WDE may be disposed to overlap the anode electrode AND of the pixel PX on the welding point WP. Accordingly, the anode electrode AND of the pixel PX may be formed to be directly connected to the welding electrode WDE. In other words, when the repair process is performed through the laser, at least a portion of the fourth insulating layer ILD4, the third insulating layer ILD3, and the second insulating layer ILD2 overlapping the welding point WP is destroyed, such that the anode electrode AND and the welding electrode WDE may be electrically connected.

As another example, in the display device DD, the second auxiliary line AXL2 may be omitted. In this case, at least a part of the welding electrode WDE is disposed to overlap the pad electrode LPD, and the pad electrode LPD may be electrically connected to the welding electrode WDE through at least one contact hole penetrating at least a part of the fourth insulating layer ILD4, the third insulating layer ILD3, and the second insulating layer ILD2.

Further, even though in FIG. 5, it is described that the welding point WP is formed at a position where the welding electrode WDE and the first auxiliary line AXL1 overlap each other, example embodiments of the present disclosure are not limited thereto.

For example, the welding point WP may be formed at a position where the first auxiliary line AXL1 and the intermediate electrode ITE overlap. In this case, unlike the embodiment illustrated in FIG. 5, the welding electrode WDE and the first auxiliary line AXL1 may be electrically connected to each other through at least one contact hole, for example, at least one contact hole penetrating the second insulating layer ILD2. In addition, the first auxiliary line AXL1 and the intermediate electrode ITE may be formed to be connected to each other. For example, a welding point WP is formed on a position where the first auxiliary line AXL1 and the intermediate electrode ITE overlap, and when a repair process is performed through a laser, at least a part of the third insulating layer ILD3 overlapping the welding point WP is destroyed so that the first auxiliary line AXL1 and the intermediate electrode ITE may be electrically connected.

FIGS. 6 and 7 are views for explaining an example of a defective pixel repair process of a display device according to an example embodiment of the present disclosure. For example, FIGS. 6 and 7 illustrate an example of a case in which the corresponding pixel PX is determined as a defective pixel and a repair process is performed. FIG. 6 corresponds to a circuit diagram of the pixel PX described with reference to FIG. 2, and FIG. 7 may correspond to a cross-sectional view described with reference to FIG. 5.

With reference to FIGS. 6 and 7, when the pixel PX is determined to be a defective pixel, a repair process may be performed on the corresponding pixel PX. For example, as illustrated in FIG. 7, when the laser is irradiated onto the welding point WP by the repair process, at least a part of the second insulating layer ILD2 overlapping the welding point WP among the second insulating layers ILD2 disposed between the first auxiliary line AXL1 and the welding electrode WDE may be destroyed. Accordingly, the first auxiliary line AXL1 may be electrically connected by contacting the welding electrode WDE exposed by the laser. Depending on the embodiment, the laser may be irradiated from top to bottom, for example, in a direction opposite to the third direction Z, but is not limited thereto.

In this case, the first auxiliary line AXL1 and the second auxiliary line AXL2 may be electrically connected by the welding electrode WDE. Accordingly, as illustrated in FIG. 6, the driving current flowing through the pixel PX by the driving transistor DT may not flow from the fourth node N4 to the second power line PL2 via the light emitting element LD, but may flow on the current path flowing through the second power line PL2 via the auxiliary line AXL. Accordingly, the light emitting element LD does not emit light, and the corresponding pixel PX may be darkened. Accordingly, the corresponding pixel PX, which is a defective pixel, may be repaired.

Meanwhile, as described above, because the pad electrode LPD is disposed and formed between adjacent pixels PX, even if a laser is irradiated on the welding point WP in such a repair process, the laser to which the pad electrode LPD is irradiated is shielded to prevent the laser from being irradiated to another pixel PX adjacent to a defective pixel, for example, a transistor included in a normal pixel.

For example, when a laser is irradiated onto the welding point WP during the repair process, the laser may be unintentionally irradiated or energy may be applied to other components around the welding point WP due to optical characteristics. As shown in FIGS. 4 and 5, as the pad electrode LPD is positioned adjacent to the welding point WP, the amount of energy applied to the peripheral component during laser irradiation may be reduced.

In addition, among the transistors included in the pixel PX, the above-described oxide semiconductor transistor, for example, the second transistor T2 and the third transistor T3, are particularly vulnerable to the laser so that when the laser is irradiated, a threshold voltage shift occurs and their characteristics may change. Here, in the display device DD according to an example embodiment of the present disclosure, even though the laser repair process for the defective pixel is performed, the laser irradiated by the pad electrode LPD is shielded to prevent the laser from being irradiated to the pixel PX adjacent to the defective pixel. For example, as described above, the laser irradiated onto the welding point WP by the repair process may be irradiated from the top to the bottom of the display device DD, for example, in a direction opposite to the third direction Z. Here, the pad electrode LPD is disposed above the fourth insulating layer ILD4, and thus, is disposed above the above-described oxide semiconductor transistor, for example, the second transistor T2 and the third transistor T3. Therefore, even though the laser is irradiated from the top to the bottom, the laser is shielded by the pad electrode LPD, and the second transistor T2 and the third transistor T3 may be prevented from being irradiated with laser beams. Accordingly, even if the repair process of the defective pixel is performed, the threshold voltage shift of the transistors included in the adjacent pixel PX may be prevented.

Further, in the case of a related art defective pixel repair process, a cutting process of cutting at least one line positioned on the current path of the driving current of the corresponding pixel and a welding process of connecting the cut line to the dummy line connected to the dummy pixel are included, whereas in the repair process for the defective pixel of the display device DD according to an example embodiment of the present disclosure, only a laser welding process of connecting the auxiliary line AXL to the welding electrode WDE may be performed to repair the defective pixel. Accordingly, compared to the related art defective pixel repair process, the defective pixel repair process of the display device DD according to an example embodiment of the present disclosure may be minimized, or at least reduced.

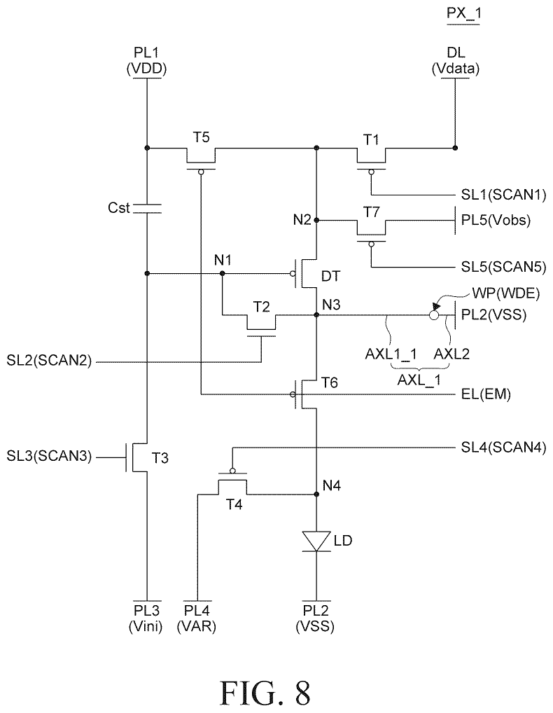

FIG. 8 is a view for explaining another example of a defective pixel repair process of a display device according to an example embodiment of the present disclosure.

Meanwhile, the pixel PX_1 illustrated in FIG. 8 represents another embodiment of the pixel PX included in the display panel DP of the display device DD that has been described with reference to FIG. 1. For example, the pixel PX_1 of FIG. 8 represents a modified embodiment of the pixel PX described with reference to FIG. 2, and accordingly, redundant descriptions will not be repeated.

With reference to FIG. 8, the pixel PX_1 may include a light emitting element LD, a driving transistor DT, a plurality of transistors T1 to T7, and a storage capacitor Cst.

In an embodiment, the auxiliary line AXL_1 may be connected to at least one node connected to the pixel circuit included in the pixel PX_1, for example, at least one node on the current path of the driving current described above. For example, the auxiliary line AXL_1 may be electrically connected to the third node N3 between the driving transistor DT and the sixth transistor T6.

The auxiliary line AXL_1 may include a first auxiliary line AXL1_1 disposed between the third node N3 and the welding point WP and a second auxiliary line AXL2 disposed between the welding point WP and the second power line PL2. Here, as described above, the second auxiliary line AXL2 may be electrically connected to the welding electrode WDE and the second power line PL2.

Here, one end of the first auxiliary line AXL1_1 may be electrically connected to the third node N3, and the other end of the first auxiliary line AXL1_1 may be formed to be connected to the welding electrode WDE. Accordingly, when the pixel PX_1 is determined as a defective pixel and the repair process is performed, the first auxiliary line AXL1_1 and the welding electrode WDE may be electrically connected, such that the first auxiliary line AXL1_1 and the second auxiliary line AXL2 may be electrically connected by the welding electrode WDE.

Accordingly, the driving current flowing through the pixel PX_1 by the driving transistor DT may flow on the current path flowing through the second power line PL2 via the auxiliary line AXL_1 at the third node N3. Accordingly, the light emitting element LD does not emit light, and the corresponding pixel PX_1 may be darkened. Accordingly, the corresponding pixel PX_1, which is a defective pixel, may be repaired.

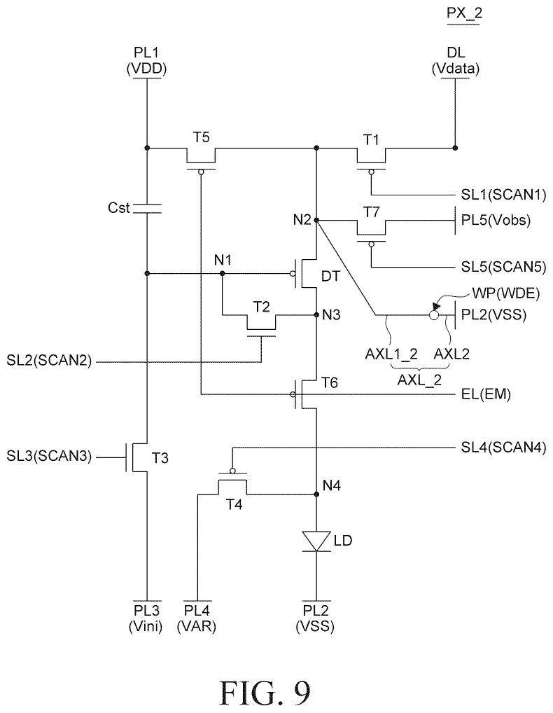

FIG. 9 is a view for explaining another example of a defective pixel repair process of a display device according to an example embodiment of the present disclosure.

In the meantime, the pixel PX_2 illustrated in FIG. 9 represents still another example of the pixel PX included in the display panel DP of the display device DD that has been described with reference to FIG. 1. For example, the pixel PX_2 of FIG. 9 represents a modified embodiment of the pixel PX described with reference to FIG. 2, and accordingly, redundant descriptions will not be repeated.

With reference to FIG. 9, the pixel PX_2 may include a light emitting element LD, a driving transistor DT, a plurality of transistors T1 to T7, and a storage capacitor Cst.

In an embodiment, the auxiliary line AXL_2 may be connected to at least one node connected to the pixel circuit included in the pixel PX_2, for example, at least one node on the current path of the driving current described above. For example, the auxiliary line AXL_2 may be electrically connected to the second node N2 between the fifth transistor T5 and the driving transistor DT.

The auxiliary line AXL_2 may include a first auxiliary line AXL1_2 disposed between the second node N2 and the welding point WP and a second auxiliary line AXL2 disposed between the welding point WP and the second power line PL2. Here, as described above, the second auxiliary line AXL2 may be electrically connected to the welding electrode WDE and the second power line PL2.

Here, one end of the first auxiliary line AXL1_2 may be electrically connected to the second node N2, and the other end of the first auxiliary line AXL1_2 may be connected to the welding electrode WDE. Accordingly, when the pixel PX_2 is determined as a defective pixel and the repair process is performed, the first auxiliary line AXL1_2 and the welding electrode WDE may be electrically connected, such that the first auxiliary line AXL1_2 and the second auxiliary line AXL2 may be electrically connected by the welding electrode WDE.

Accordingly, the driving current flowing in the corresponding pixel PX_2 by the driving transistor DT may flow on the current path flowing from the second node N2 to the second power line PL2 via the auxiliary line AXL_2. Accordingly, the light emitting element LD does not emit light, and the corresponding pixel PX_2 may be darkened. Accordingly, the corresponding pixel PX_2, which is a defective pixel, may be repaired.

As described above, according to an example embodiment of the present disclosure, a repair process for a defective pixel may be performed through a laser welding process for an auxiliary line connected to at least one node connected to a pixel circuit included in pixels PX, PX_1, and PX_2.

In addition, because the pad electrode LPD for the repair process according to an example embodiment of the present disclosure is disposed between adjacent pixels PX, even if a laser is irradiated on the welding point WP in the repair process, the laser is shielded by the pad electrode LPD to prevent the laser from being irradiated to a normal pixel adjacent to a defective pixel. Accordingly, the threshold voltage shift of the transistor included in the normal pixel that may occur during the repair process may be prevented.

Further, unlike the related art defective pixel repair process, in an example embodiment of the present disclosure, only a laser welding process for connecting the auxiliary line AXL to the welding electrode WDE is performed to repair the defective pixel, so that the repair process may be minimized or at least reduced.

Hereinafter, a structure connected to a plurality of subpixels of one pad electrode will be described.

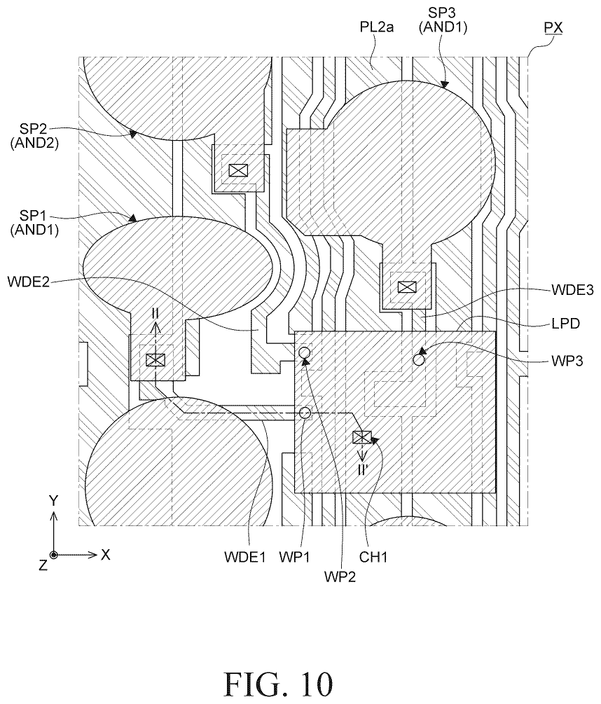

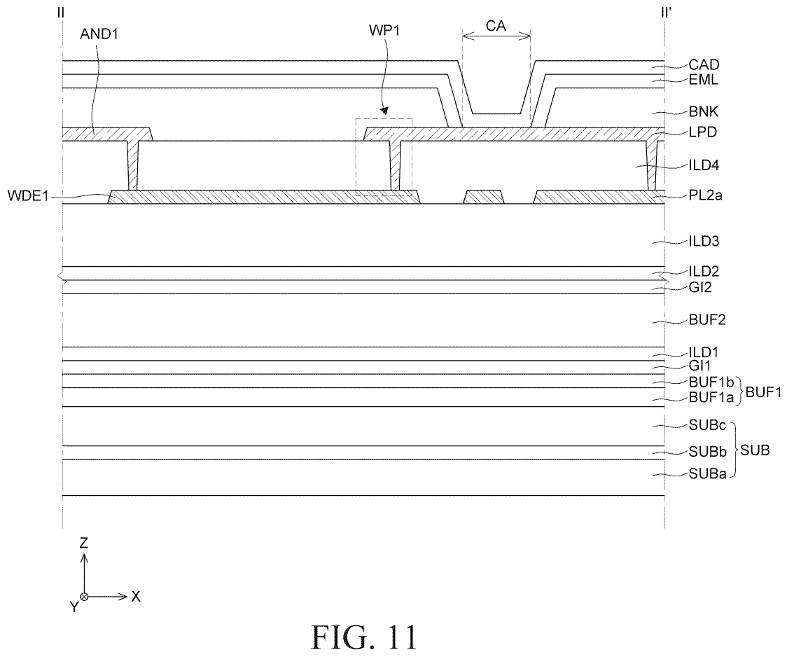

FIG. 10 is a schematic enlarged plan view of a display panel included in a display device according to another example embodiment of the present disclosure. FIG. 11 is a cross-sectional view illustrating an example taken along line II-II′ of FIG. 10.

Meanwhile, for convenience of description, in FIGS. 10 and 11, descriptions overlapping with those described with reference to FIGS. 4 to 7 will not be repeated. For example, FIG. 10 is an enlarged plan view illustrating one pixel PX of the display panel DP included in the display device DD described with reference to FIGS. 1 to 3, and schematically illustrates an example of lines connected thereto and a plurality of subpixels SP1, SP2, and SP3 are disposed in one pixel PX.

One pixel PX may include a plurality of subpixels SP1, SP2, and SP3 emitting light of different colors. For example, one pixel PX may include a first subpixel SP1, a second subpixel SP2, and a third subpixel SP3. For example, each of the first subpixel SP1, the second subpixel SP2, and the third subpixel SP3 may be any one of a red subpixel, a green subpixel, and a blue subpixel, but is not limited thereto.

Each of the plurality of subpixels SP1, SP2, and SP3 includes an emission area in which light is emitted and a non-emission area in which light is not emitted. For convenience of description, in FIG. 10, an area in which an anode electrode for providing an emission area is disposed is displayed together as each subpixel. In this case, the first subpixel SP1 may include a first anode electrode AND1, the second subpixel SP2 may include a second anode electrode AND2, and the third subpixel SP3 may include a third anode electrode AND3.

One pad electrode LPD may be disposed between the plurality of subpixels SP1, SP2, and SP3. For example, one pad electrode LPD may be disposed in each pixel PX. In this case, one pad electrode LPD may be electrically connected to the plurality of subpixels SP1, SP2, and SP3 disposed in one pixel PX at the same time. The pad electrode LPD may be connected to the second sub-power line PL2a through a through hole CH1. Accordingly, the pad electrode LPD may electrically connect each of the subpixels SP1, SP2, and SP3 and the second sub power line PL2a.

With reference to FIG. 10, each pad electrode LPD may be disposed adjacent to the first subpixel SP1, the second subpixel SP2, and the third subpixel SP3 in one pixel PX. The pad electrode LPD may be connected to each of the subpixels SP1, SP2, and SP3. For example, the pad electrode LPD may be connected to the welding electrodes WDE1, WDE2, and WDE3 connected to the subpixels SP1, SP2, and SP3. For example, the pad electrode LPD may be connected to the first subpixel SP1 through the first welding electrode WDE1, connected to the second subpixel SP2 through the second welding electrode WDE2, and connected to the third subpixel SP3 through the third welding electrode WDE3. When the repair process is performed by each of the welding electrodes WDE1, WDE2, and WDE3, each of the subpixels SP1, SP2, and SP3 may be electrically connected to the pad electrode LPD. In this case, each of the welding electrodes WDE1, WDE2, and WDE3 may be connected to at least one node included in the pixel circuit of each of the subpixels SP1, SP2, and SP3, for example, an anode electrode AND1, AND2, and AND3 connected to a fourth node. However, for convenience of description, FIGS. 10 and 11 illustrate that the welding electrodes WDE1, WDE2, and WDE3 are directly connected to and in contact with the anode electrodes AND1, AND2, and AND3.

For example, as illustrated in FIGS. 10 and 11 together, the pad electrode LPD may be connected to the first welding electrode WDE1. One end of the first welding electrode WDE1 may be electrically connected to the first anode electrode AND1 of the first subpixel SP1. Further, the other end of the first welding electrode WDE1 overlaps at least a part of the pad electrode LPD to be connected to the pad electrode LPD through at least one contact hole.

As shown in FIG. 11, in an embodiment, the first welding electrode WDE1 may be disposed on the third insulating layer ILD3. The first welding electrode WDE1 may be disposed on the same layer as the second sub-power line PL2a and may include the same material.

The other end of the first welding electrode WDE1 may overlap the pad electrode LPD on the first welding point WP1. Accordingly, when a repair process of irradiating the pad electrode LPD, which is a connectable structure, is performed on the first welding point WP1, the first welding electrode WDE1 and the pad electrode LPD are in contact with each other, thereby electrically connecting to the first anode electrode AND1 of the first subpixel SP1 and the second sub power line PL2a that provides the second power voltage VSS.

In this case, the first welding electrode WDE1 is disposed on the same layer as the second sub-power line PL2a so that the first welding electrode WDE1 may not be connected to directly contact the second sub-power line PL2a, but may be electrically connected to the second sub-power line PL2a through the pad electrode LPD.

Like the first subpixel SP1, when a repair process of irradiating the second welding point WP2 with laser beams is performed, the second subpixel SP2 may be connected to the pad electrode LPD through the second welding electrode WDE2. Further, when the repair process of irradiating the third welding point WP3 with laser beams is performed, the third subpixel SP3 may be connected to the pad electrode LPD through the third welding electrode WDE3.

In comparison with the display device according to the embodiment illustrated in FIGS. 4 to 7, in FIGS. 10 and 11, auxiliary lines connected to the subpixels SP1, SP2, SP3 and the pad electrode LPD with the welding electrodes WDE1, WDE2, and WDE3 interposed therebetween may be excluded. In this case, the welding electrodes WDE1, WDE2, and WDE3 may be in direct contact with the circuit of the subpixel, for example, the anode electrodes AND1, AND2, and AND3 and the pad electrode LPD, without an auxiliary line. In this case, each of the welding points WP1, WP2, and WP3 may be formed in a region where the welding electrodes WDE1, WDE2, and WDE3 and the pad electrode LPD overlap.

However, the present disclosure is not limited thereto, and as in the display device according to the embodiment illustrated in FIGS. 4 to 7, an auxiliary line may be further included. For example, a first auxiliary line connected to the anode electrode included in the subpixel and a second auxiliary line connected to the pad electrode LPD may be formed with a welding point therebetween. In this case, the welding point may be formed in a region where the welding electrodes WDE1, WDE2, and WDE3 and the auxiliary line overlap.

Further, even though in FIGS. 10 and 11, it has been described that the welding electrodes WDE1, WDE2, and WDE3 are disposed on the third insulating layer ILD3, it is not limited thereto. For example, the welding electrodes WDE1, WDE2, and WDE3 may be disposed on the second insulating layer ILD2 and may be connected to the anode electrodes AND1, AND2, and AND3 and the pad electrodes LPD of the subpixels SP1, SP2, and SP3 through contact holes simultaneously penetrating the second insulating layer ILD2 and the third insulating layer ILD3.

In the display device according to another example embodiment of the present disclosure, by using the pad electrode LPD for improving the voltage drop of the light emitting element, a repair process for a defective pixel may be performed through a laser welding process in which the pad electrode LPD and the welding electrodes WDE1, WDE2, and WDE3 are connected. In particular, by connecting one pad electrode LPD to the plurality of subpixels SP1, SP2, and SP3, the area in which the pad electrode LPD is disposed may be reduced, which may help to secure a margin for pixel design.

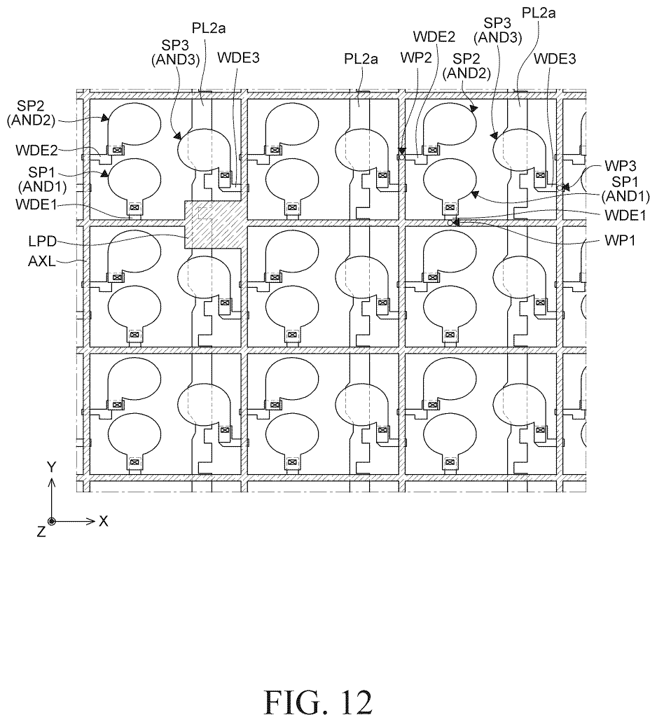

FIG. 12 is a schematic enlarged plan view of a display panel included in a display device according to still another example embodiment of the present disclosure.

A display device illustrated in FIG. 12 has the substantially same configurations as the display device illustrated in FIGS. 10 and 11, except that a placement structure of the pad electrode LPD is different and an auxiliary line AXL is further disposed on the same layer as the pad electrode LPD. Therefore, a redundant description will be omitted.

With reference to FIG. 12, one pad electrode LPD may be disposed per a plurality of subpixels SP1, SP2, and SP3. Unlike a structure in which the pad electrode LPD is disposed for each unit pixel PX in the display device illustrated in FIGS. 10 and 11, the display device illustrated in FIG. 12 may have a small number of pad electrodes LPD and a small density. For example, one pad electrode LPD may be disposed per nine unit pixels including the first subpixel SP1, the second subpixel SP2, and the third subpixel SP3, but is not limited thereto. For example, the pad electrode LPD may be disposed only in a part of the entire display area of the display device. Accordingly, one pad electrode LPD may be electrically connected to subpixels included in a plurality of pixels through a repair process.

The pad electrode LPD may be connected to the plurality of subpixels SP1, SP2, and SP3 through the auxiliary line AXL. For example, the auxiliary line AXL is disposed on the same layer as the pad electrode LPD and the anode electrodes AND1, AND2, and AND3 and may include the same material. In this case, the auxiliary line AXL may include a plurality of lines, and each of the lines may extend in the first direction X and/or the second direction Y and extend to be spaced apart from each other. In this case, each line may be disposed between each pixel or may be disposed in a non-emission area. Further, with reference to FIG. 12, the auxiliary line AXL may have a mesh shape or a mesh pattern shape. For example, the auxiliary line AXL may have a shape extending in the first direction X and the second direction Y so that a plurality of lines surround each pixel. In this case, the auxiliary line AXL is disposed to be in contact with the pad electrode LPD. For example, at least one side of the pad electrode LPD may be disposed to be shared with the auxiliary line AXL.

The auxiliary lines AXL are electrically insulated from each other without performing the repair process by the welding electrodes WDE1, WDE2, and WDE3 which are connectable structures, and may be electrically connected to each other when the repair process is performed.

With reference to FIG. 12, each of the plurality of first subpixels SP1, the second subpixels SP2, and the third subpixels SP3 is connected to the welding electrodes WDE1, WDE2, and WDE3. For example, the first subpixel SP1 is connected to the first welding electrode WDE1, the second subpixel SP2 is connected to the second welding electrode WDE2, and the third subpixel SP3 is connected to the third welding electrode WDE3. One end of each of the welding electrodes WDE1, WDE2, and WDE3 may be electrically connected to the anode electrodes AND1, AND2, and AND3 of each of the subpixels SP1, SP2, and SP3. Further, the other ends of the respective welding electrodes WDE1, WDE2, and WDE3 are disposed at the welding points WP1, WP2, and WP3 to overlap at least a part of the auxiliary line AXL. In one example embodiment, the net-shaped auxiliary line AXL overlaps the other ends of the plurality of welding electrodes WDE1, WDE2, and WDE3 whose one end is connected to the plurality of subpixels SP1, SP2, and SP3 in the non-emission area of the pixel. Accordingly, when the repair process of irradiating laser to the auxiliary line AXL, which is a connectable structure, on the welding points WP1, WP2, and WP3, is performed, the auxiliary line AXL and the welding electrodes WDE1, WDE2, and WDE3 may be electrically connected to each other.

According to the presence or absence of the repair process, the anode electrodes AND1, AND2, and AND3 connected to at least one node included in the pixel circuit of the subpixels SP1, SP2, and SP3, for example, the fourth node, are electrically connected to the pad electrode LPD through the auxiliary line AXL and the welding electrodes WDE1, WDE2, and WDE3. Therefore, each of the anode electrodes AND1, AND2, and AND3 may receive the second power voltage VSS from the second sub power line PL2a in contact with the pad electrode LPD through the pad electrode LPD.

In the display device according to still another example embodiment of the present disclosure, by using the pad electrode LPD for improving the voltage drop of the light emitting element, a repair process for a defective pixel may be performed through a laser welding process in which the pad electrode LPD and the welding electrodes WDE1, WDE2, and WDE3 are connected. In particular, in the case where the pad electrode LPD is formed only in a partial area, the pad electrode LPD and all subpixels are connected through the auxiliary line AXL having a net shape to perform a repair process and minimize, or at least reduce, an area occupied by the pad electrode LPD.

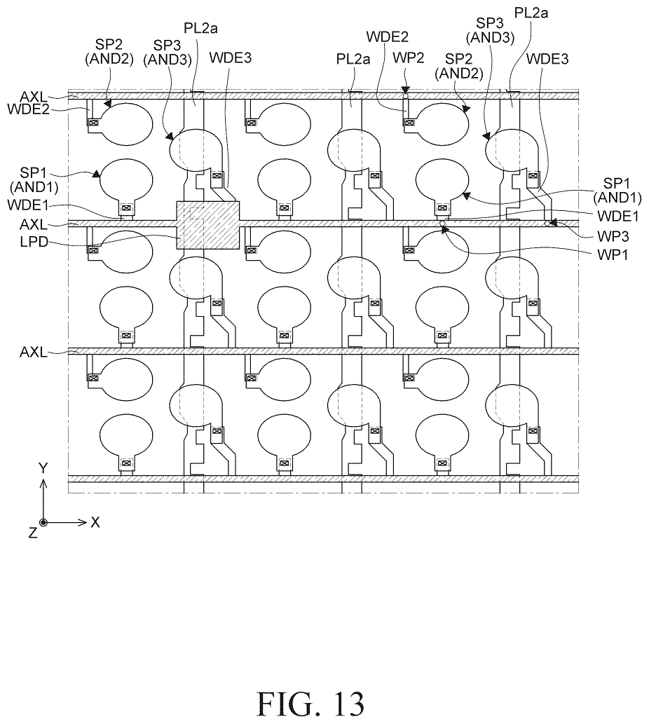

FIG. 13 is a schematic enlarged plan view of a display panel included in a display device according to still another example embodiment of the present disclosure. A display device illustrated in FIG. 13 has the substantially same configurations as the display device illustrated in FIG. 12 except that structures of auxiliary lines are different so that a redundant description will be omitted.

With reference to FIG. 13, the auxiliary line AXL includes a plurality of auxiliary lines AXL extending in the first direction X and arranged to be spaced apart from each other in the second direction Y. The embodiment of the present disclosure is not limited thereto, and the plurality of auxiliary lines AXL may extend in the second direction Y and may be spaced apart from each other in the first direction X. Each auxiliary line AXL may be disposed between each unit pixel or may be disposed in a non-emission area. When the repair process is performed, each of the auxiliary lines AXL may be electrically connected to adjacent subpixels in the second direction Y.

With reference to FIG. 13, each of the plurality of first subpixels SP1, the second subpixels SP2, and the third subpixels SP3 is connected to the welding electrodes WDE1, WDE2, and WDE3. For example, the first subpixel SP1 is connected to the first welding electrode WDE1, the second subpixel SP2 is connected to the second welding electrode WDE2, and the third subpixel SP3 is connected to the third welding electrode WDE3. One end of each of the welding electrodes WDE1, WDE2, and WDE3 may be electrically connected to the anode electrodes AND1, AND2, and AND3 of the subpixels SP1, SP2, and SP3. In this case, the subpixels SP1, SP2, and SP3 in one pixel may be connected to different auxiliary lines AXL. For example, the second welding electrode WDE2 electrically connected to the second subpixel SP2 may be connected to the auxiliary line AXL different from the first welding electrode WDE1 electrically connected to the first subpixel SP1 and the third welding electrode WDE3 electrically connected to the third subpixel SP3.

When a repair process of irradiating a laser to the plurality of auxiliary lines AXL which is a connectable structure on the welding points WP1, WP2, and WP3 is performed, the plurality of auxiliary lines AXL and the welding electrodes WDE1, WDE2, and WDE3 may be electrically connected to each other.

The example embodiments of the present disclosure can also be described as follows:

According to an aspect of the present disclosure, there is provided a display device. The display device includes a substrate, a pixel circuit on the substrate and connected between a first power line configured to provide a first power voltage and a second power line configured to provide a second power voltage, and a light emitting element connected to the pixel circuit, a welding electrode on the substrate, a first auxiliary line having one end connected to at least one node connected to the pixel circuit and the other end disposed to be connectable to the welding electrode, and a second auxiliary line having one end connected to the welding electrode and the other end connected to the second power line.

The welding electrode may be on a same layer as a gate electrode included in at least one transistor included in the pixel and may include a same material.

The at least one transistor may be an oxide semiconductor transistor.

The display device may further comprise a pad electrode on the substrate and on the second power line with the pad electrode in contact with the second power line.

The pad electrode may be disposed on a same layer as an anode electrode of the light emitting element and may include a same material.

At least a part of the light emitting layer of the light emitting element on the pad electrode may be removed to expose at least a part of the pad electrode, and the cathode electrode of the light emitting element may be in contact with the exposed at least a part of the pad electrode.

One end of the first auxiliary line may be electrically connected to the pixel circuit and the other end of the first auxiliary line overlaps the welding electrode so that the first auxiliary line is connectable to the welding electrode. One end of the second auxiliary line may be electrically connected to the welding electrode and the other end of the second auxiliary line may be electrically connected to the pad electrode.

The display device may further comprise at least one insulating layer disposed between the first auxiliary line and the second auxiliary line and the welding electrode, wherein the first auxiliary line may be disposed to overlap at least a part of a welding electrode, and the second auxiliary line may be in contact with the welding electrode through a contact hole penetrating the at least one insulating layer.

Each of the first auxiliary line and the second auxiliary line may be on a same layer as the source electrode and the drain electrode of at least one transistor included in the pixel and may include a same material.

The at least one transistor may be a polysilicon semiconductor transistor.

The display device may further comprise at least one insulating layer between the second auxiliary line and the second power line, wherein the second power line may be in contact with the second auxiliary line through a contact hole penetrating the at least one insulating layer.

The second power line may be on a same layer as the source electrode and the drain electrode of at least one transistor included in the pixel and may include a same material.

The at least one transistor may be an oxide semiconductor transistor.

The display device may further comprise at least one insulating layer between the pad electrode and the second power line, wherein the pad electrode may be in contact with the second power line through a contact hole penetrating the at least one insulating layer.

The pixel circuit may include a driving transistor connected between a second node and a third node and including a gate electrode connected to a first node; a first transistor connected between the second node and a data line and including a gate electrode connected to a first scan line; a second transistor connected between the first node and the third node and including a gate electrode connected to a second scan line; a third transistor connected between the first node and a third power line providing an initialization voltage and including a gate electrode connected to a third scan line; a fourth transistor connected between a fourth node corresponding to an anode electrode of the light emitting element and a fourth power line providing a reset voltage and including a gate electrode connected to a fourth scan line; a fifth transistor connected between the first power line and the second node and including a gate electrode connected to a light emission control line; a sixth transistor connected between the third node and the fourth node and including a gate electrode connected to the light emission control line; and a seventh transistor connected between the second node and a fifth power line providing a bias voltage and including a gate electrode connected to a fifth scan line.

The first auxiliary line may be connected to one of the second node, the third node, and the fourth node.

According to another aspect of the present disclosure, there is provided a display device. The display device comprises a substrate on which a plurality of unit pixels each including a plurality of subpixels is defined; a first power line configured to supply a first power voltage to each of the plurality of subpixels; and a second power line configured to supply a second power voltage to each of the plurality of subpixels. Each of the plurality of subpixels may include a pixel circuit on the substrate, the pixel circuit connected between the first power line and the second power line; a light emitting element connected to the pixel circuit; a welding electrode on the substrate; and a pad electrode electrically connected to the second power line and having a portion partially exposed to electrically connect to a cathode electrode of the light emitting element, wherein one end of the welding electrode is electrically connected to either at least one node of the pixel circuit or the second power lines, and the other end of the welding electrode is disposed to be connectable to the other one of the at least one node or the second power line.

Each of the plurality of subpixels may further include a first auxiliary line connected to the pixel circuit and over the welding electrode; and a second auxiliary line connected to the second power line and over the welding electrode, wherein any one of the first auxiliary line and the second auxiliary line may be connected to the welding electrode and the other one of the first auxiliary line and the second auxiliary line may be connectable to the welding electrode.

One end of the second auxiliary line may be in direct contact with the second power line, and the second power line may be in direct contact with the pad electrode.

Each of the plurality of subpixels may further include at least one insulating layer between the welding electrode and the second power line and between the welding electrode and the pad electrode, wherein the welding electrode may be disposed on a same layer as the second power line, and the welding electrode may at least partially overlap the pad electrode.

Each of the plurality of subpixels may include a welding electrode configured to connect with the pad electrode, and the pad electrode may be configured to be connectable to the plurality of welding electrodes.

Each of the plurality of unit pixels may include a first subpixel, a second subpixel, and a third subpixel, the welding electrode may include a first welding electrode connected to the first subpixel, a second welding electrode connected to the second subpixel, and a third welding electrode connected to the third subpixel, and the first welding electrode, the second welding electrode, and the third welding electrode at least partially may overlap the pad electrode.

The pad electrode may overlap a plurality of welding electrodes connected to subpixels disposed in at least two or more unit pixels.

The display device may further comprise an auxiliary line disposed on a same layer as the pad electrode and in direct contact with the pad electrode, wherein the auxiliary line may overlap at least a respective portion of each of the first, second, and third welding electrodes.

The auxiliary line may include a plurality of auxiliary lines between the plurality of unit pixels and elongated in at least one direction.

The auxiliary line may include an auxiliary line between the plurality of unit pixels and has a net shape.

According to another aspect of the present disclosure, there is provided a repair method of a display device. The display device includes a substrate; a pixel on the substrate and having a pixel circuit connected between a first power line configured to provide a first power voltage and a second power line configured to provide a second power voltage, and a light emitting element connected to the pixel circuit; a welding electrode on the substrate; a first auxiliary line having one end connected to at least one node connected to the pixel circuit and the other end disposed to be connectable to the welding electrode; and a second auxiliary line having one end connected to the welding electrode and the other end connected to the second power line. The repair method may comprise a step of electrically connecting the first auxiliary line and the welding electrode through a laser welding process when the pixel is a defective pixel.

According to another aspect of the present disclosure, there is provided a display device. The display device may comprise a substrate; a pixel on the substrate, the pixel including: a pixel circuit connected between a first power line configured to supply a first power voltage and a second power line configured to supply a second power voltage, and a light emitting element connected to the pixel circuit; a welding electrode on the substrate; an insulating layer on the welding electrode; a first auxiliary line having a first end thereof connected to the pixel circuit and a second end thereof over the welding electrode with the insulating layer therebetween; and a second auxiliary line having a first end thereof over the welding electrode with the insulating layer therebetween and a second end thereof connected to the second power line, wherein one of the first auxiliary line and the second auxiliary line is connected to the welding electrode through the insulating layer.

The other one of the first auxiliary line and the second auxiliary line may be separated from the welding electrode by the insulating layer in an unrepaired state.

The first auxiliary line and the second auxiliary line may be electrically separated in an unrepaired state.

The other one of the first auxiliary line and the second auxiliary line may be configured to be connectable to the welding electrode through the insulating layer by laser welding.

It will be apparent to those skilled in the art that various modifications and variations can be made in the display device and the repairing method thereof of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a pixel on the substrate, the pixel including a pixel circuit connected between a first power line configured to supply a first power voltage and a second power line configured to supply a second power voltage, and a light emitting element connected to the pixel circuit;
a welding electrode on the substrate;
a first auxiliary line having one end connected to at least one node connected to the pixel circuit and the other end disposed to be connectable to the welding electrode; and
a second auxiliary line having one end connected to the welding electrode and the other end connected to the second power line.

2. The display device according to claim 1, wherein the pixel further includes at least one transistor having a gate electrode, and wherein the welding electrode is on a same layer as the gate electrode and includes a same material as the gate electrode, and
wherein the at least one transistor is an oxide semiconductor transistor.

3. The display device according to claim 1, further comprising a pad electrode on the substrate and on the second power line, the pad electrode being in contact with the second power line.

4. The display device according to claim 3, wherein the light emitting element includes a an cathode electrode;
wherein the light emitting layer of the light emitting element is absent over a part of the pad electrode to expose the part of the pad electrode, and
wherein the cathode electrode of the light emitting element is in contact with the part of the pad electrode.

5. The display device according to claim 3, wherein one end of the first auxiliary line is electrically connected to the pixel circuit and the other end of the first auxiliary line overlaps the welding electrode so that the first auxiliary line is connectable to the welding electrode, and
one end of the second auxiliary line is electrically connected to the welding electrode, and the other end of the second auxiliary line is electrically connected to the pad electrode.

6. The display device according to claim 5, further comprising at least one insulating layer disposed between the first auxiliary line and the second auxiliary line and the welding electrode,
wherein the first auxiliary line is disposed to overlap at least a part of a welding electrode, and
wherein the second auxiliary line is in contact with the welding electrode through a contact hole penetrating the at least one insulating layer.

7. The display device according to claim 6, wherein the pixel further includes at least one transistor having a source electrode and a drain electrode,
wherein each of the first auxiliary line and the second auxiliary line is on a same layer as the source electrode and the drain electrode,
wherein each of the first auxiliary line and the second auxiliary line includes a same material as the source electrode and the drain electrode, and
wherein the at least one transistor is a polysilicon semiconductor transistor.

8. The display device according to claim 5, further comprising at least one insulating layer between the second auxiliary line and the second power line, wherein the second power line is in contact with the second auxiliary line through a contact hole penetrating the at least one insulating layer.

9. The display device according to claim 8, wherein the pixel further includes at least one transistor having a source electrode and a drain electrode,
wherein the second power line is on a same layer as the source electrode and the drain electrode,
wherein the second power line includes a same material as the source electrode and the drain electrode, and
wherein the at least one transistor is an oxide semiconductor transistor.

10. The display device according to claim 5, further comprising at least one insulating layer between the pad electrode and the second power line, wherein the pad electrode is in contact with the second power line through a contact hole penetrating the at least one insulating layer.

11. The display device according to claim 1, wherein the pixel circuit includes:
a driving transistor connected between a second node and a third node and including a gate electrode connected to a first node;
a first transistor connected between the second node and a data line and including a gate electrode connected to a first scan line;
a second transistor connected between the first node and the third node and including a gate electrode connected to a second scan line;
a third transistor connected between the first node and a third power line providing an initialization voltage and including a gate electrode connected to a third scan line;
a fourth transistor connected between a fourth node corresponding to an anode electrode of the light emitting element and a fourth power line providing a reset voltage and including a gate electrode connected to a fourth scan line;
a fifth transistor connected between the first power line and the second node and including a gate electrode connected to a light emission control line;
a sixth transistor connected between the third node and the fourth node and including a gate electrode connected to the light emission control line; and
a seventh transistor connected between the second node and a fifth power line providing a bias voltage and including a gate electrode connected to a fifth scan line,
wherein the first auxiliary line is connected to one of the second node, the third node, and the fourth node.

12. A display device, comprising:
a substrate on which a plurality of unit pixels each including a plurality of subpixels is defined;
a first power line configured to supply a first power voltage to each of the plurality of subpixels; and
a second power line configured to supply a second power voltage to each of the plurality of subpixels,
wherein each of the plurality of subpixels includes:
a pixel circuit on the substrate, the pixel circuit connected between the first power line and the second power line;
a light emitting element connected to the pixel circuit;
a welding electrode on the substrate; and
a pad electrode electrically connected to the second power line and having a portion partially exposed to electrically connect to a cathode electrode of the light emitting element,
wherein one end of the welding electrode is electrically connected to one of at least one node of the pixel circuit and the second power lines, and the other end of the welding electrode is connectable to the other one of the at least one node and the second power line.

13. The display device according to claim 12, wherein each of the plurality of subpixels further includes:
a first auxiliary line connected to the pixel circuit and over the welding electrode; and
a second auxiliary line connected to the second power line and over welding electrode,
wherein one of the first auxiliary line and the second auxiliary line is connected to the welding electrode, and
wherein the other one of the first auxiliary line and the second auxiliary line is disposed to be connectable to the welding electrode.

14. The display device according to claim 13, wherein one end of the second auxiliary line is in direct contact with the second power line, and
wherein the second power line is in direct contact with the pad electrode.

15. The display device according to claim 12, wherein each of the plurality of subpixels further includes:
at least one insulating layer between the welding electrode and the second power line and between the welding electrode and the pad electrode,
wherein the welding electrode is disposed on a same layer as the second power line, and
the welding electrode at least partially overlaps the pad electrode.

16. The display device according to claim 12, wherein each of the plurality of subpixels includes a welding electrode configured to connect with the pad electrode, and
wherein the pad electrode is configured to be connectable to the plurality of welding electrodes.

17. The display device according to claim 16, wherein each of the plurality of unit pixels includes a first subpixel, a second subpixel, and a third subpixel,
wherein the welding electrode includes a first welding electrode connected to the first subpixel, a second welding electrode connected to the second subpixel, and a third welding electrode connected to the third subpixel, and
wherein the first welding electrode, the second welding electrode, and the third welding electrode at least partially overlap the pad electrode.

18. The display device according to claim 17, wherein the pad electrode overlaps a plurality of welding electrodes connected to subpixels disposed in two or more unit pixels.

19. The display device according to claim 18, further comprising:
an auxiliary line disposed on a same layer as the pad electrode and in direct contact with the pad electrode,
wherein the auxiliary line overlaps at least a respective portion of each of the first, second, and third welding electrodes, and
wherein the auxiliary line includes a plurality of auxiliary lines between the plurality of unit pixels and elongated in at least one direction, or an auxiliary line between the plurality of unit pixels and has a net shape.

20. A repair method of a display device, the display device including
a substrate;
a pixel on the substrate and having a pixel circuit connected between a first power line configured to provide a first power voltage and a second power line configured to provide a second power voltage, and a light emitting element connected to the pixel circuit;
a welding electrode on the substrate;
a first auxiliary line having one end connected to at least one node connected to the pixel circuit and the other end disposed to be connectable to the welding electrode; and
a second auxiliary line having one end connected to the welding electrode and the other end connected to the second power line,
the repair method comprising a step of electrically connecting the first auxiliary line and the welding electrode through a laser welding process when the pixel is a defective pixel.

21. A display device, comprising:
a substrate;
a pixel on the substrate, the pixel including:
a pixel circuit connected between a first power line configured to supply a first power voltage and a second power line configured to supply a second power voltage, and
a light emitting element connected to the pixel circuit;
a welding electrode on the substrate;
an insulating layer on the welding electrode;
a first auxiliary line having a first end thereof connected to the pixel circuit and a second end thereof over the welding electrode with the insulating layer therebetween; and
a second auxiliary line having a first end thereof over the welding electrode with the insulating layer therebetween and a second end thereof connected to the second power line,
wherein one of the first auxiliary line and the second auxiliary line is connected to the welding electrode through the insulating layer,
wherein the other one of the first auxiliary line and the second auxiliary line is separated from the welding electrode by the insulating layer in an unrepaired state, and
the other one of the first auxiliary line and the second auxiliary line is configured to be connectable to the welding electrode through the insulating layer by laser welding.
